(19) United States
(12) Patent Application Publication
(10) Pub. No.: US 2025/0017077 A1
(43) Pub. Date: Jan. 9, 2025

(54) DISPLAY DEVICE AND MANUFACTURING METHOD OF THE SAME

(71) Applicant: Samsung Display Co., LTD., Yongin-si (KR)

(72) Inventor: WONWOO CHOI, Yongin-si (KR)

(21) Appl. No.: 18/634,685

(22) Filed: Apr. 12, 2024

(30) Foreign Application Priority Data
Jul. 7, 2023 (KR) 10-2023-0088539

(51) Int. Cl. H10K 59/80; H10K 59/12; H10K 102/00

(52) U.S. Cl. CPC H10K 59/80; H10K 59/1201; H10K 2102/311

(57) ABSTRACT

A display device includes a display panel including a first non-folding region, a folding region, and a second non-folding region arranged in a first direction, a plurality of panel protection layers disposed under the first non-folding region and the second non-folding region, and a filling part that is disposed between the plurality of panel protection layers and that overlaps the folding region. A lower surface of the filling part has a height greater than or equal to each of heights of lower surfaces of the plurality of panel protection layers.

This application claims priority to Korean Patent Application No. 10-2023-0088539, filed on Jul. 7, 2023, and all the benefits accruing therefrom under 35 U.S.C. § 119, the content of which in its entirety is herein incorporated by reference.

### BACKGROUND

### 1. Field

Embodiments of the disclosure described herein relate to a display device and a manufacturing method thereof.

### 2. Description of the Related Art

An electronic device, such as a smart phone, a digital camera, a notebook computer, a car navigation unit, a smart television, or the like, which provides an image to a user includes a display device for displaying an image. The display device generates an image and provides the image to the user through a display screen.

With the development of display device technology, various forms of display devices are being developed. For example, various display devices that may be curved, folded, or rolled are being developed. The display devices may be easy to carry and may improve user convenience.

A display device may include a display panel and a panel protection layer for protecting a lower portion of the display panel. When the display panel is folded, the panel protection layer attached to the display panel may be folded together with the display panel.

### SUMMARY

Embodiments of the disclosure provide a display device capable of being more easily folded while improving the impact resistance (the resistance to an external impact) of non-folding regions.

In an embodiment, a display device includes a display panel including a first non-folding region, a folding region, and a second non-folding region arranged in a first direction, a plurality of panel protection layers disposed under the first non-folding region and the second non-folding region, and a filling part that is disposed between the plurality of panel protection layers and that overlaps the folding region. A lower surface of the filling part has a height greater than or equal to each of heights of lower surfaces of the plurality of panel protection layers.

In an embodiment, a display device includes a display panel including a first non-folding region, a folding region, and a second non-folding region arranged in a first direction, an adhesive layer disposed under the display panel, a plurality of panel protection layers disposed under the adhesive layer and spaced apart from each other in the folding region, and a filling part that is disposed between the plurality of panel protection layers and that overlaps the folding region. The filling part has a thickness less than or equal to a sum of a thickness of the plurality of panel protection layers and a thickness of the adhesive layer.

In an embodiment, a method for manufacturing a display device includes providing an adhesive layer under a display panel including a first non-folding region, a folding region, and a second non-folding region arranged in a first direction, providing a preliminary panel protection layer under the adhesive layer, forming panel protection layers by removing a portion of the preliminary panel protection layer that overlaps the folding region, and filling a filling part in a space that overlaps the folding region and that is defined between the panel protection layers. A lower surface of the filling part has a height greater than or equal to each of heights of lower surfaces of the panel protection layers.

### BRIEF DESCRIPTION OF THE DRAWINGS

The above and other embodiments, advantages and features of the disclosure will become apparent by describing in detail embodiments thereof with reference to the accompanying drawings.

FIG. 1 is a perspective view of an embodiment of an electronic device according to the disclosure.

FIGS. 2A and 2B are views illustrating folded states of the electronic device illustrated in FIG. 1.

FIG. 3 is an exploded perspective view of the electronic device illustrated in FIG. 1.

FIG. 4 is a block diagram of the electronic device illustrated in FIG. 3.

FIG. 5 is a schematic cross-sectional view of a display module illustrated in FIG. 3.

FIG. 6 is a cross-sectional view of a display panel illustrated in FIG. 5.

FIG. 7 is a plan view of the display panel illustrated in FIG. 3.

FIG. 8 is a view illustrating a section of an electronic panel corresponding to any one pixel illustrated in FIG. 7.

FIG. 9A is a cross-sectional view taken along line I-I′ illustrated in FIG. 7.

FIG. 9B is a view illustrating a state in which a bending region illustrated in FIG. 9A is bent.

FIG. 10A is a view for explaining yield strain of a filling part illustrated in FIG. 9A.

FIG. 10B is a view for explaining yield strain.

FIG. 10C is a view for explaining strain of a thin film encapsulation layer illustrated in FIG. 5.

FIG. 10D is a view for explaining a repulsive force of a window illustrated in FIG. 9A.

FIG. 11 is a view illustrating an embodiment of a display device according to the disclosure.

FIG. 12 is a view illustrating an embodiment of a display device according to the disclosure.

FIGS. 13A to 13C are views for explaining an embodiment of a display device according to the disclosure.

FIGS. 14A to 14C are views for explaining a method of manufacturing the display device illustrated in FIG. 9A.

### DETAILED DESCRIPTION

The above and other features and advantages of the disclosure will become apparent from the following description of embodiments given in conjunction with the accompanying drawings. However, the disclosure is not limited to the embodiments disclosed herein and may be implemented in various different forms. Herein, the embodiments are provided to provide complete disclosure of the disclosure and to provide thorough understanding of the disclosure to those skilled in the art to which the disclosure pertains, and the scope of the disclosure should be limited only by the accompanying claims and equivalents thereof. Like reference numerals refer to like elements throughout.

When one element or layer is referred to as being “on” another element or layer, it can be directly on the other element or layer, or intervening elements or layers may be present. In contrast, when one element is referred to as being “directly on” another element or layer, there are no intervening elements or layers present. As used herein, the term “and/or” includes each of mentioned items and all combinations of one or more of the items.

Spatially relative terms, such as “below”, “beneath”, “lower”, “above”, “upper” and the like, may be used to easily describe a correlation between one element or component and another element or component as illustrated in the drawings. The spatially relative terms should be understood as terms including different directions of an element during use or operation in addition to the direction illustrated in the drawings. Like reference numerals refer to like elements throughout.

Although the terms “first,” “second,” and the like are used herein to describe various elements, components, and/or sections, these elements, components, and/or sections should not be limited by these terms. These terms are only used to distinguish one element, component, or section from another element, component, or section. Accordingly, a first element, a first component, or a first section mentioned below could be termed a second element, a second component, or a second section within the spirit and scope of the disclosure.

Embodiments described herein will be described with reference to plan views and cross-sectional views which are ideal schematic views of the disclosure. Accordingly, the forms of illustrative drawings may be changed according to manufacturing technology and/or allowable errors. Embodiments of the disclosure are not limited to specific forms illustrated, but include changes in the forms generated according to manufacturing processes. Regions illustrated in the drawings have schematic properties, and the shapes of the regions illustrated in the drawings illustrate specific forms of regions of devices and are not intended to limit the scope of the disclosure.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). The term such as “about” can mean within one or more standard deviations, or within ±30%, 20%, 10%, 5% of the stated value, for example.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Hereinafter, embodiments of the disclosure will be described in more detail with reference to the accompanying drawings.

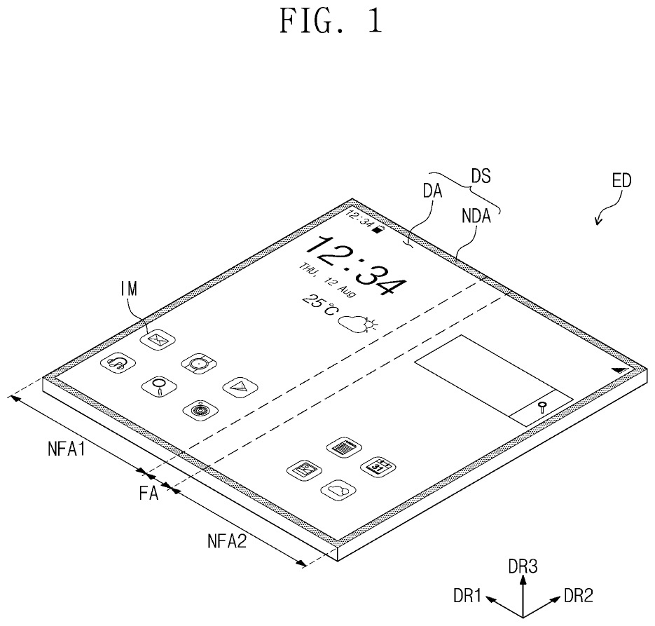

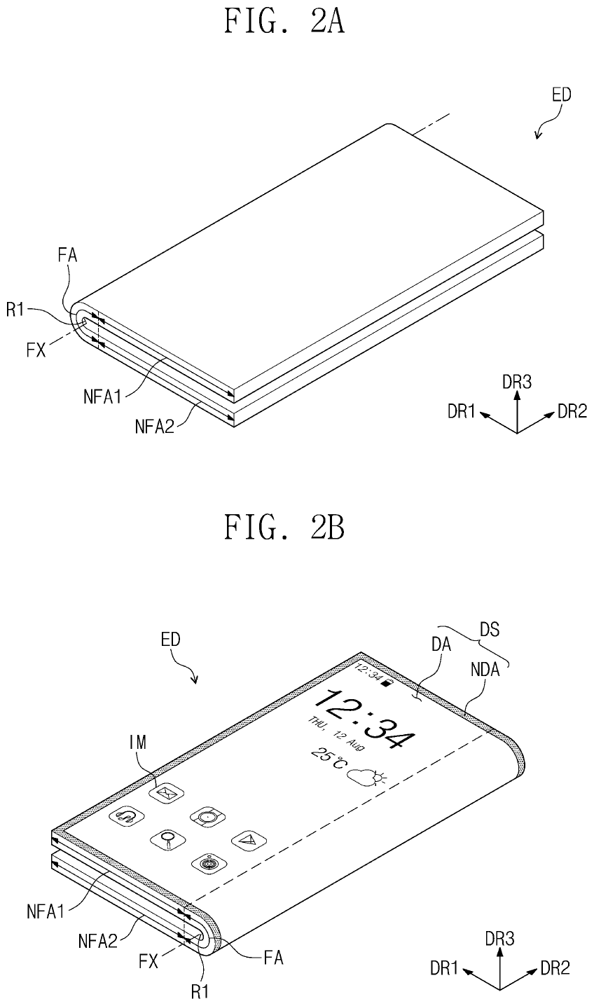

FIG. 1 is a perspective view of an embodiment of an electronic device according to the disclosure. FIGS. 2A and 2B are views illustrating folded states of the electronic device illustrated in FIG. 1.

Referring to FIG. 1, the electronic device ED in an embodiment of the disclosure may have a quadrangular shape, e.g., rectangular shape with short sides extending in a first direction DR1 and long sides extending in a second direction DR2 crossing the first direction DR1. However, without being limited thereto, the electronic device ED may have various shapes such as a circular shape, a polygonal shape, or the like. The electronic device ED may be a flexible electronic device.

Hereinafter, a direction substantially vertically crossing a plane defined by the first direction DR1 and the second direction DR2 is defined as a third direction DR3. Furthermore, the expression “when viewed from above the plane” used herein may mean that it is viewed in third direction DR3.

The electronic device ED may include a folding region FA and a plurality of non-folding regions NFA1 and NFA2. The non-folding regions NFA1 and NFA2 may include the first non-folding region NFA1 and the second non-folding region NFA2. The folding region FA may be disposed between the first non-folding region NFA1 and the second non-folding region NFA2. The folding region FA, the first non-folding region NFA1, and the second non-folding region NFA2 may be disposed in the first direction DR1.

Although one folding region FA and two non-folding regions NFA1 and NFA2 are illustrated in an embodiment, the number of folding regions FA and the number of non-folding regions NFA1 and NFA2 are not limited thereto. In an embodiment, the electronic device ED may include more than two non-folding regions and a plurality of folding regions, each of which is disposed between the non-folding regions, for example.

An upper surface of the electronic device ED may be defined as a display surface DS, and the display surface DS may have a plane defined by the first direction DR1 and the second direction DR2. Images IM generated by the electronic device ED may be provided to a user through the display surface DS.

The display surface DS may include a display region DA and a non-display region NDA around the display region DA. The display region DA may display an image, and the non-display region NDA may not display an image. The non-display region NDA may surround the display region DA and may define a border of the electronic device ED that is printed in a predetermined color.

Referring to FIGS. 2A and 2B, the electronic device ED may be a foldable electronic device ED that is folded or unfolded. In an embodiment, the folding region FA may be bent about a folding axis FX parallel to the second direction DR2, and the electronic device ED may be folded accordingly, for example. The folding axis FX may be defined as a long axis parallel to the long sides of the electronic device ED. When the electronic device ED is folded, the first non-folding region NFA1 and the second non-folding region NFA2 may face each other, and the electronic device ED may be folded in an in-folding manner such that the display surface DS is not exposed to the outside. However, the disclosure is not limited thereto. In an embodiment, as illustrated in FIG. 2B, the electronic device ED may be folded outward about the folding axis FX such that the display surface DS is exposed to the outside, for example. In addition, although not illustrated, in-folding and out-folding may be simultaneously performed on the electronic device ED. In an embodiment, the folding region FA may have a curvature radius R1 in the bent state.

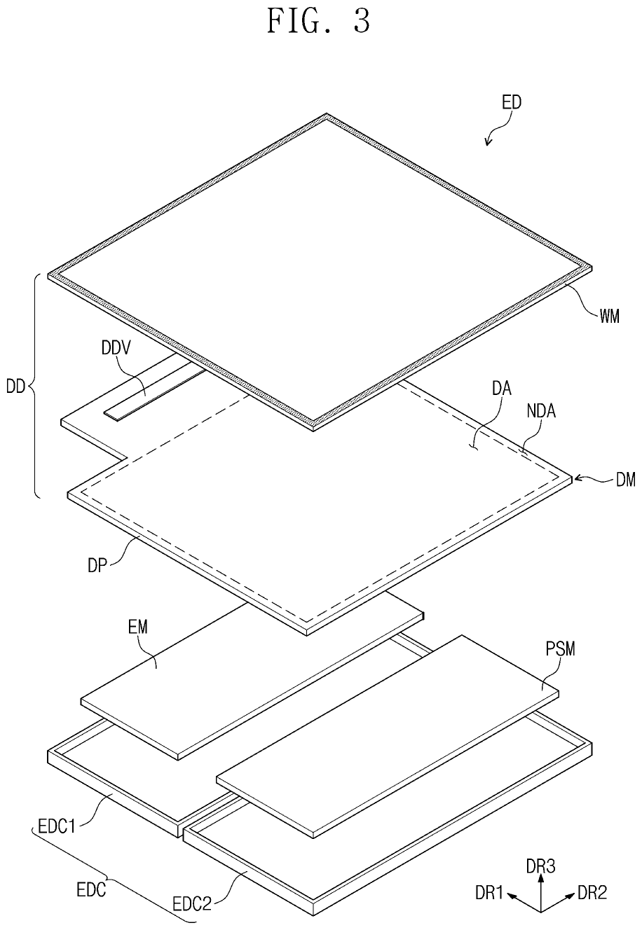

FIG. 3 is an exploded perspective view of the electronic device illustrated in FIG. 1.

Referring to FIG. 3, the electronic device ED may include a display device DD, an electronic module EM, a power supply module PSM, and a case EDC. Although not illustrated, the electronic device ED may further include a mechanical structure (e.g., a hinge) for controlling a folding operation of the display device DD.

The display device DD may generate an image and may sense an external input. The display device DD may include a window module WM and a display module DM. The window module WM may provide a front surface of the electronic device ED. The window module WM may be disposed on the display module DM and may protect the display module DM. The window module WM may pass light generated from the display module DM and may provide the light to the user.

The display module DM may include a display panel DP. Although only the display panel DP among stacked structures of the display module DM is illustrated in FIG. 3, the display module DM may substantially further include a plurality of components disposed on and under the display panel DP. A detailed stacked structure of the display module DM will be described below in detail. The display panel DP may include a display region DA and a non-display region NDA that correspond to the display region DA and the non-display region NDA of the electronic device ED.

The display module DM may include a data driver DDV disposed on the non-display region NDA of the display panel DP. The data driver DDV may be manufactured in the form of an integrated circuit chip and may be disposed (e.g., mounted) on the non-display region NDA. However, without being limited thereto, the data driver DDV may be disposed (e.g., mounted) on a flexible circuit board connected to the display panel DP.

The electronic module EM and the power supply module PSM may be disposed under the display device DD. Although not illustrated, the electronic module EM and the power supply module PSM may be connected with each other through a separate flexible circuit board. The electronic module EM may control operation of the display device DD. The power supply module PSM may supply power to the electronic module EM.

The case EDC may accommodate the display device DD, the electronic module EM, and the power supply module PSM. To fold the display device DD, the case EDC may include a first case EDC1 and a second case EDC2. The first and second cases EDC1 and EDC2 may extend in the second direction DR2 and may be arranged in the first direction DR1.

Although not illustrated, the electronic device ED may further include a hinge structure for connecting the first case EDC1 and the second case EDC2. The case EDC may be coupled with the window module WM. The case EDC may protect the display device DD, the electronic module EM, and the power supply module PSM.

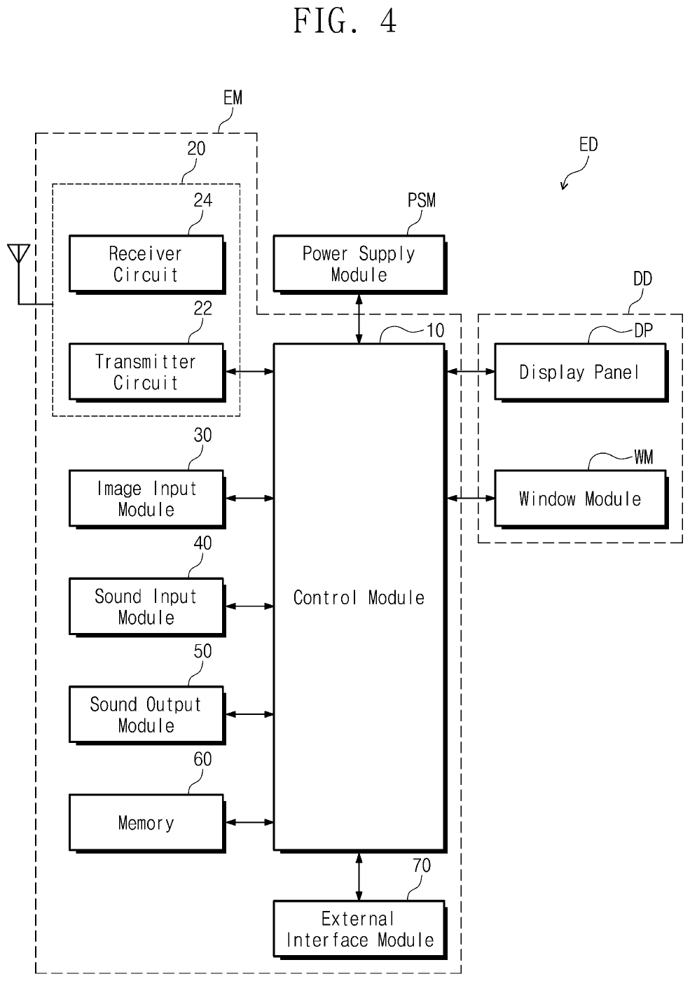

FIG. 4 is a block diagram of the electronic device illustrated in FIG. 3.

Referring to FIG. 4, the electronic device ED may include the electronic module EM, the power supply module PSM, and the display device DD. The electronic module EM may include a control module 10, a wireless communication module 20, an image input module 30, a sound input module 40, a sound output module 50, a memory 60, and an external interface module 70. The modules may be disposed (e.g., mounted) on a circuit board, or may be electrically connected through a flexible circuit board. The electronic module EM may be electrically connected with the power supply module PSM.

The control module 10 may control overall operation of the electronic device ED. In an embodiment, the control module 10 may activate or deactivate the display device DD in response to a user input, for example. The control module 10 may control the image input module 30, the sound input module 40, and the sound output module 50 in response to a user input. The control module 10 may include at least one microprocessor.

The wireless communication module 20 may transmit/receive wireless signals with another terminal through Bluetooth or Wi-Fi. The wireless communication module 20 may transmit/receive sound signals using a general communication line. The wireless communication module 20 may include a transmitter circuit 22 that modulates a signal to be transmitted and transmits the modulated signal and a receiver circuit 24 that demodulates a received signal.

The image input module 30 may process an image signal to covert the image signal into image data that may be displayed on the display device DD. The sound input module 40 may receive an external sound signal through a microphone in a voice recording mode or a voice recognition mode and may convert the external sound signal into electrical voice data. The sound output module 50 may convert sound data received from the wireless communication module 20 or sound data stored in the memory 60 and may output the converted sound data to the outside.

The external interface module 70 may serve as an interface connected to an external charger, a wired/wireless data port, or a card socket (e.g., a memory card or a subscriber identity module/user identity module (“SIM/UIM”) card).

The power supply module PSM may supply power desired for overall operation of the electronic device ED. The power supply module PSM may include a conventional battery device.

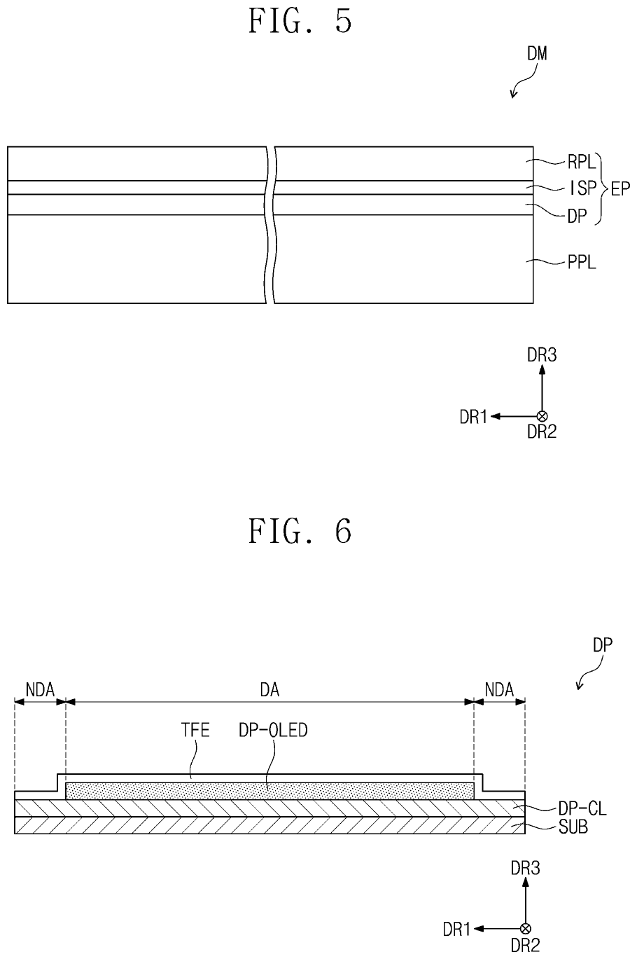

FIG. 5 is a schematic cross-sectional view of the display module illustrated in FIG. 3.

Referring to FIG. 5, the display module DM may include the display panel DP, an input sensing unit ISP disposed on the display panel DP, an anti-reflective layer RPL disposed on the input sensing unit ISP, and a panel protection layer PPL disposed under the display panel DP. The display panel DP may be a flexible display panel. In an embodiment, the display panel DP may include a flexible substrate and a plurality of elements disposed on the flexible substrate, for example.

The display panel DP in an embodiment of the disclosure may be an emissive display panel, but is not particularly limited. In an embodiment, the display panel DP may be an organic light-emitting display panel or an inorganic light-emitting display panel, for example. An emissive layer of the organic light-emitting display panel may include an organic light-emitting material. An emissive layer of the inorganic light-emitting display panel may include quantum dots, quantum rods, or the like. Hereinafter, it will be exemplified that the display panel DP is an organic light-emitting display panel.

The input sensing unit ISP may include a plurality of sensor units (not illustrated) for sensing an external input in a capacitive type. The input sensing unit ISP may be directly formed on the display panel DP when the display module DM is manufactured.

The anti-reflective layer RPL may be disposed on the input sensing unit ISP. The anti-reflective layer RPL may be directly formed on the input sensing unit ISP when the display module DM is manufactured. The anti-reflective layer RPL may be defined as a film for preventing reflection of external light. The anti-reflective layer RPL may decrease the reflectance of external light incident toward the display panel DP from above the display device DD.

In an embodiment, the input sensing unit ISP may be directly formed on the display panel DP, and the anti-reflective layer RPL may be directly formed on the input sensing unit ISP, for example. However, the disclosure is not limited thereto. In an embodiment, the input sensing unit ISP may be separately manufactured and may be attached to the display panel DP by an adhesive layer, and the anti-reflective layer RPL may be separately manufactured and may be attached to the input sensing unit ISP by an adhesive layer, for example.

The display panel DP, the input sensing unit ISP, and the anti-reflective layer RPL may be defined as an electronic panel EP.

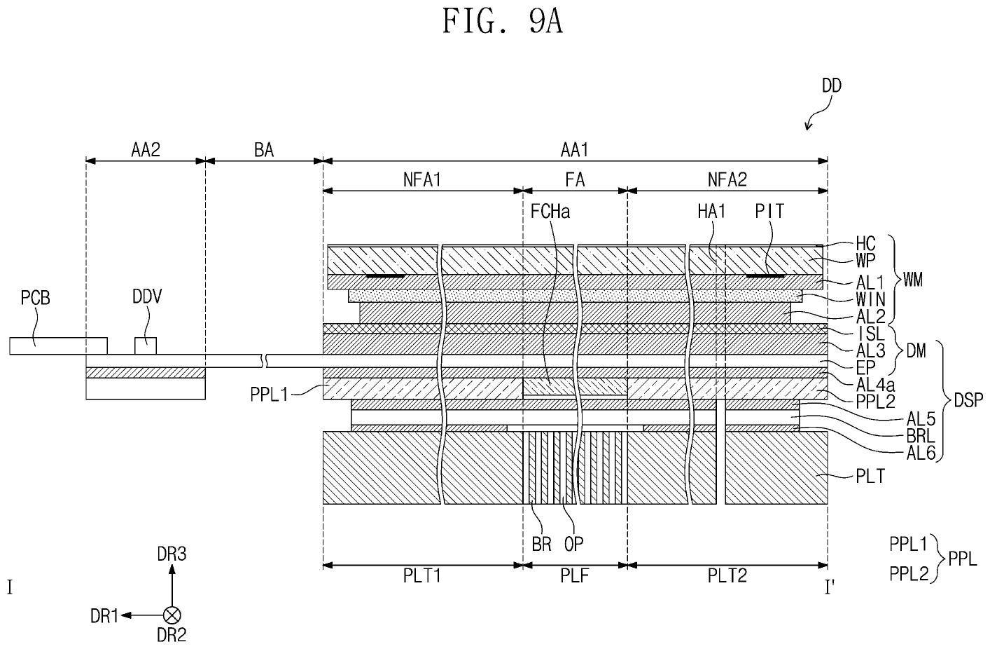

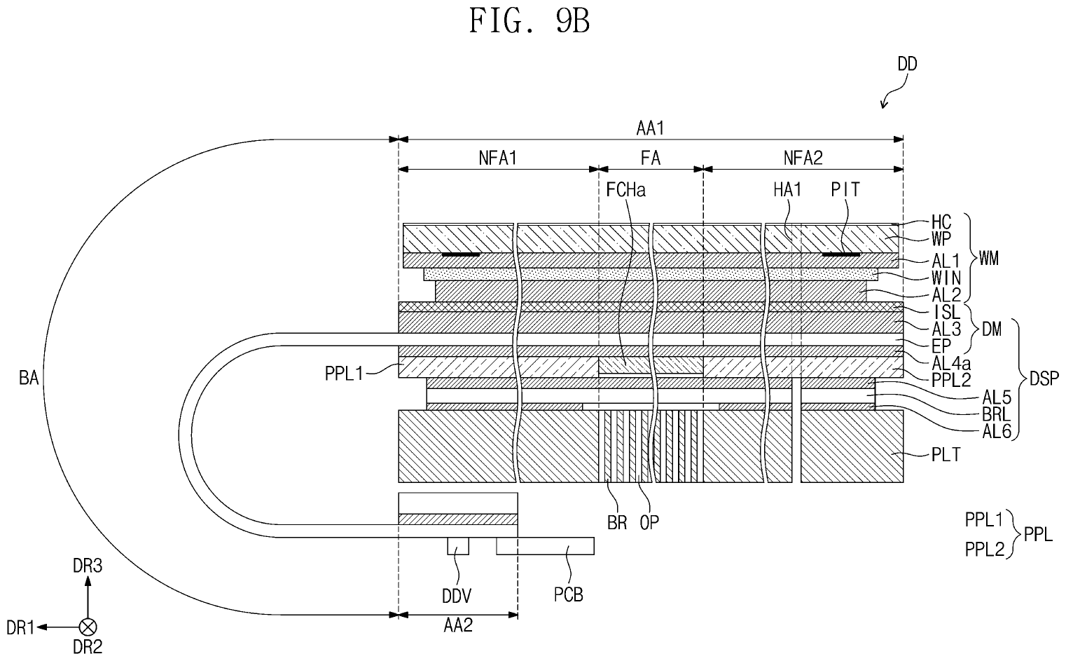

The panel protection layer PPL may be disposed under the display panel DP. The panel protection layer PPL may protect a lower portion of the display panel DP. The panel protection layer PPL may include a flexible plastic material. In an embodiment, the panel protection layer PPL may include polyethylene terephthalate (“PET”), for example. Although the panel protection layer PPL is illustrated as one unitary layer in FIG. 5, the panel protection layer PPL may include two layers spaced apart from each other. Detailed description thereabout will be given below with reference to FIG. 9A.

FIG. 6 is a cross-sectional view of the display panel illustrated in FIG. 5.

In FIG. 6, a section of the display panel DP viewed in the second direction DR2 is illustrated.

Referring to FIG. 6, the display panel DP may include a substrate SUB, a circuit element layer DP-CL disposed on the substrate SUB, a display element layer DP-OLED disposed on the circuit element layer DP-CL, and a thin film encapsulation layer TFE disposed on the display element layer DP-OLED.

The substrate SUB may include a display region DA and a non-display region NDA around the display region DA. The substrate SUB may include a flexible plastic material such as glass or polyimide (“PI”). The display element layer DP-OLED may be disposed on the display region DA.

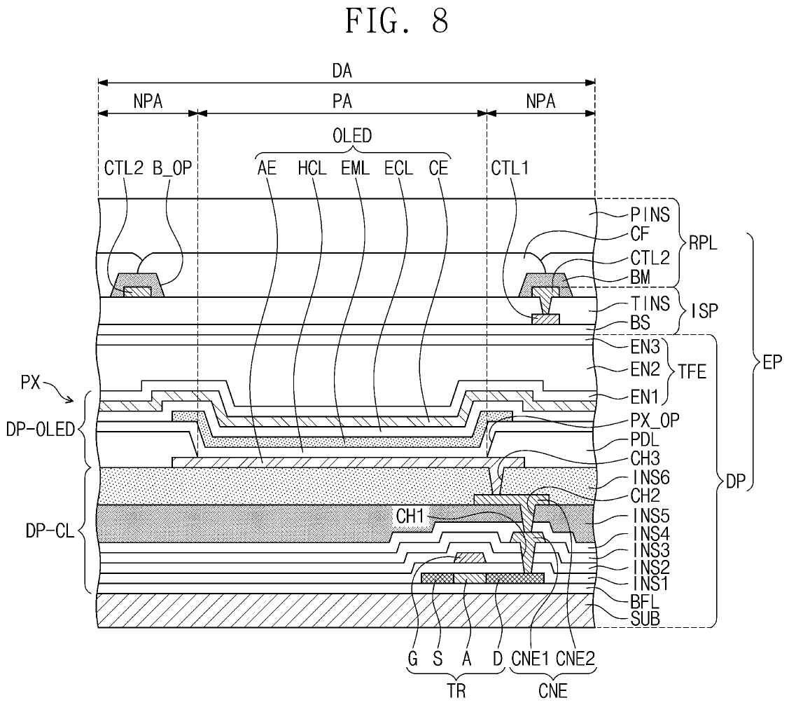

A plurality of pixels may be disposed in the circuit element layer DP-CL and the display element layer DP-OLED. Each of the pixels may include transistors disposed in the circuit element layer DP-CL and a light-emitting element disposed in the display element layer DP-OLED and connected to the transistors. A configuration of the pixel will be described below in detail with reference to FIG. 8.

The thin film encapsulation layer TFE may be disposed on the circuit element layer DP-CL to cover the display element layer DP-OLED. The thin film encapsulation layer TFE may protect the pixels from moisture, oxygen, and external foreign matter.

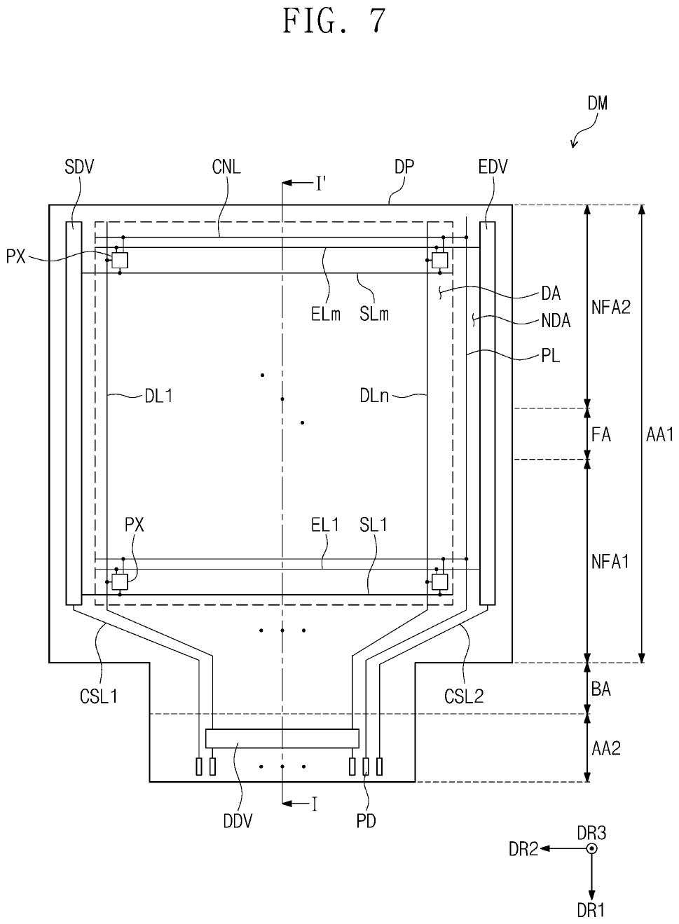

FIG. 7 is a plan view of the display panel illustrated in FIG. 3.

Referring to FIG. 7, the display module DM may include the display panel DP, a scan driver SDV, the data driver DDV, and an emission driver EDV.

The display panel DP may include a first region AA1, a second region AA2, and a bending region BA between the first region AA1 and the second region AA2. The bending region BA may extend in the second direction DR2, and the first region AA1, the bending region BA, and the second region AA2 may be arranged in the first direction DR1.

The first region AA1 may include a display region DA and a non-display region NDA around the display region DA. The non-display region NDA may surround the display region DA. The display region DA may be a region that displays an image, and the non-display region NDA may be a region that does not display an image. The second region AA2 and the bending region BA may be regions that do not display an image.

The first region AA1, when viewed in the second direction DR2, may include a first non-folding region NFA1, a second non-folding region NFA2, and a folding region FA between the first non-folding region NFA1 and the second non-folding region NFA2.

The display panel DP may include a plurality of pixels PX, a plurality of scan lines SL1 to SLm, a plurality of data lines DL1 to DLn, a plurality of emission lines EL1 to ELm, first and second control lines CSL1 and CSL2, a power line PL, a plurality of connecting lines CNL, and a plurality of pads PD. Here, “m” and “n” are natural numbers. The pixels PX may be disposed in the display region DA and may be connected to the scan lines SL1 to SLm, the data lines DL1 to DLn, and the emission lines EL1 to ELm.

The scan driver SDV and the emission driver EDV may be disposed in the non-display region NDA. The scan driver SDV and the emission driver EDV may be disposed in the non-display regions NDA adjacent to opposite sides of the first region AA1 that are opposite each other in the second direction DR2. The data driver DDV may be disposed in the second region AA2. The data driver DDV may be manufactured in the form of an integrated circuit chip and may be disposed (e.g., mounted) on the second region AA2.

The scan lines SL1 to SLm may extend in the second direction DR2 and may be connected to the scan driver SDV. The data lines DL1 to DLn may extend in the first direction DR1 and may be connected to the data driver DDV via the bending region BA. The emission lines EL1 to ELm may extend in the second direction DR2 and may be connected to the emission driver EDV.

The power line PL may extend in the first direction DR1 and may be disposed in the non-display region NDA. The power line PL may be disposed between the display region DA and the emission driver EDV. However, without being limited thereto, the power line PL may be disposed between the display region DA and the scan driver SDV.

The power line PL may extend to the second region AA2 via the bending region BA. The power line PL may extend toward a lower end of the second region AA2 when viewed from above the plane. The power line PL may receive a drive voltage.

The connecting lines CNL may extend in the second direction DR2 and may be arranged in the first direction DR1. The connecting lines CNL may be connected to the power line PL and the pixels PX. The drive voltage may be applied to the pixels PX through the power line PL and the connecting lines CNL connected with each other.

The first control line CSL1 may be connected to the scan driver SDV and may extend toward the lower end of the second region AA2 via the bending region BA. The second control line CSL2 may be connected to the emission driver EDV and may extend toward the lower end of the second region AA2 via the bending region BA. The data driver DDV may be disposed between the first control line CSL1 and the second control line CSL2.

The pads PD may be disposed adjacent to the lower end of the second region AA2 when viewed from above the plane. The data driver DDV, the power line PL, the first control line CSL1, and the second control line CSL2 may be connected to the pads PD.

The data lines DL1 to DLn may be connected to the corresponding pads PD through the data driver DDV. In an embodiment, the data lines DL1 to DLn may be connected to the data driver DDV, and the data driver DDV may be connected to the pads PD corresponding to the data lines DL1 to DLn, for example.

Although not illustrated, a printed circuit board may be connected to the pads PD, and a timing controller and a voltage generator may be disposed on the printed circuit board. The timing controller may be manufactured in the form of an integrated circuit chip and may be disposed (e.g., mounted) on the printed circuit board. The timing controller and the voltage generator may be connected to the pads PD through the printed circuit board.

The timing controller may control operations of the scan driver SDV, the data driver DDV, and the emission driver EDV. The timing controller may generate a scan control signal, a data control signal, and an emission control signal in response to control signals received from the outside. The voltage generator may generate the drive voltage.

The scan control signal may be provided to the scan driver SDV through the first control line CSL1. The emission control signal may be provided to the emission driver EDV through the second control line CSL2. The data control signal may be provided to the data driver DDV. The timing controller may receive image signals from the outside, may convert the data format of the image signals according to the specification of an interface with the data driver DDV, and may provide the converted signals to the data driver DDV.

The scan driver SDV may generate a plurality of scan signals in response to the scan control signal. The scan signals may be applied to the pixels PX through the scan lines SL1 to SLm. The scan signals may be sequentially applied to the pixels PX.

The data driver DDV may generate a plurality of data voltages corresponding to the image signals in response to the data control signal. The data voltages may be applied to the pixels PX through the data lines DL1 to DLn. The emission driver EDV may generate a plurality of emission signals in response to the emission control signal. The emission signals may be applied to the pixels PX through the emission lines EL1 to ELm.

The pixels PX may receive the data voltages in response to the scan signals. The pixels PX may display an image by emitting light having luminance corresponding to the data voltages in response to the emission signals. The light emission time of the pixels PX may be controlled by the emission signals.

FIG. 8 is a view illustrating a section of the electronic panel corresponding to any one pixel illustrated in FIG. 7.

Referring to FIG. 8, the pixel PX may include a transistor TR and a light-emitting element OLED. The light-emitting element OLED may include a first electrode AE (or, an anode), a second electrode CE (or, a cathode), a hole control layer HCL, an electron control layer ECL, and an emissive layer EML.

The transistor TR and the light-emitting element OLED may be disposed on the substrate SUB. Although one transistor TR is illustrated in an embodiment, the pixel PX may substantially include a plurality of transistors and at least one capacitor for driving the light-emitting element OLED.

The display region DA may include an emissive region PA corresponding to each of the pixels PX and a non-emissive region NPA around the emissive region PA. The light-emitting element OLED may be disposed in the emissive region PA.

A buffer layer BFL may be disposed on the substrate SUB. The buffer layer BFL may be an inorganic layer. A semiconductor pattern may be disposed on the buffer layer BFL. The semiconductor pattern may include poly silicon, amorphous silicon, or metal oxide.

The semiconductor pattern may be doped with an N-type dopant or a P-type dopant. The semiconductor pattern may include a heavily doped region and a lightly doped region. The heavily doped region may have a higher conductivity than that of the lightly doped region and may substantially serve as a source electrode and a drain electrode of the transistor TR. The lightly doped region may substantially correspond to an active (or, channel) region of the transistor.

The source S, the active region A, and the drain D of the transistor TR may be formed from the semiconductor pattern. A first insulating layer INS1 may be disposed on the semiconductor pattern. A gate G of the transistor TR may be disposed on the first insulating layer INS1. A second insulating layer INS2 may be disposed on the gate G. A third insulating layer INS3 may be disposed on the second insulating layer INS2.

To connect the transistor TR and the light-emitting element OLED, a connecting electrode CNE may include a first connecting electrode CNE1 and a second connecting electrode CNE2. The first connecting electrode CNE1 may be disposed on the third insulating layer INS3 and may be connected to the drain D through a first contact hole CH1 defined in the first to third insulating layers INS1 to INS3.

A fourth insulating layer INS4 may be disposed on the first connecting electrode CNE1. A fifth insulating layer INS5 may be disposed on the fourth insulating layer INS4. The second connecting electrode CNE2 may be disposed on the fifth insulating layer INS5. The second connecting electrode CNE2 may be connected to the first connecting electrode CNE1 through a second contact hole CH2 defined in the fourth and fifth insulating layers INS4 and INS5.

A sixth insulating layer INS6 may be disposed on the second connecting electrode CNE2. The layers from the buffer layer BFL to the sixth insulating layer INS6 may be defined as the circuit element layer DP-CL. The first to sixth insulating layers INS1 to INS6 may be inorganic layers or organic layers.

The first electrode AE may be disposed on the sixth insulating layer INS6. The first electrode AE may be connected to the second connecting electrode CNE2 through a third contact hole CH3 defined in the sixth insulating layer INS6. A pixel defining layer PDL in which an opening PX_OP is defined to expose a predetermined portion of the first electrode AE may be disposed on the first electrode AE and the sixth insulating layer INS6.

The hole control layer HCL may be disposed on the first electrode AE and the pixel defining layer PDL. The hole control layer HCL may include a hole transport layer and a hole injection layer.

The emissive layer EML may be disposed on the hole control layer HCL. The emissive layer EML may be disposed in a region corresponding to the opening PX_OP. The emissive layer EML may include an organic material and/or an inorganic material. The emissive layer EML may generate one of red light, green light, and blue light.

The electron control layer ECL may be disposed on the emissive layer EML and the hole control layer HCL. The electron control layer ECL may include an electron transport layer and an electron injection layer. The hole control layer HCL and the electron control layer ECL may be commonly disposed in the emissive region PA and the non-emissive region NPA.

The second electrode CE may be disposed on the electron control layer ECL. The second electrode CE may be commonly disposed in the pixels PX. The layer in which the light-emitting element OLED is disposed may be defined as the display element layer DP-OLED.

The thin film encapsulation layer TFE may be disposed on the second electrode CE and may cover the pixel PX. The thin film encapsulation layer TFE may include a first encapsulation layer EN1 disposed on the second electrode CE, a second encapsulation layer EN2 disposed on the first encapsulation layer EN1, and a third encapsulation layer EN3 disposed on the second encapsulation layer EN2.

The first and third encapsulation layers EN1 and EN3 may include inorganic insulating layers and may protect the pixel PX from moisture/oxygen. The second encapsulation layer EN2 may include an organic insulating layer and may protect the pixel PX from foreign matter such as dust particles.

A first voltage may be applied to the first electrode AE through the transistor TR, and a second voltage having a lower level than that of the first voltage may be applied to the second electrode CE. Holes and electrons injected into the emissive layer EML may be combined to form excitons, and as the excitons transition to a ground state, the light-emitting element OLED may emit light.

The input sensing unit ISP may be disposed on the thin film encapsulation layer TFE. The input sensing unit ISP may be directly manufactured on an upper surface of the thin film encapsulation layer TFE.

A base layer BS may be disposed on the thin film encapsulation layer TFE. The base layer BS may include an inorganic insulating layer. At least one inorganic insulating layer may be provided on the thin film encapsulation layer TFE as the base layer BS.

The input sensing unit ISP may include a first conductive pattern CTL1 and a second conductive pattern CTL2 disposed over the first conductive pattern CTL1. The first conductive pattern CTL1 may be disposed on the base layer BS. An insulating layer TINS may be disposed on the base layer BS to cover the first conductive pattern CTL1. The insulating layer TINS may include an inorganic insulating layer or an organic insulating layer. The second conductive pattern CTL2 may be disposed on the insulating layer TINS.

The first and second conductive patterns CTL1 and CTL2 may overlap the non-emissive region NPA. Although not illustrated, the first and second conductive patterns CTL1 and CTL2 may be disposed on the non-emissive region NPA between the emissive regions PA and may have a mesh shape.

The first and second conductive patterns CTL1 and CTL2 may form the above-described sensors of the input sensing unit ISP. In an embodiment, the first and second conductive patterns CTL1 and CTL2 having a mesh shape may be separated from each other in a predetermined region to form the sensors, for example. A portion of the second conductive pattern CTL2 may be connected to the first conductive pattern CTL1.

The anti-reflective layer RPL may be disposed on the second conductive pattern CTL2. The anti-reflective layer RPL may include a black matrix BM and a plurality of color filters CF. The black matrix BM may overlap the non-emissive region NPA, and the color filters CF may overlap the emissive regions PA, respectively.

The black matrix BM may be disposed on the insulating layer TINS to cover the second conductive pattern CTL2. An opening B_OP overlapping the emissive region PA and the opening PX_OP may be defined in the black matrix BM. The black matrix BM may absorb and block light. The width of the opening B_OP may be greater than the width of the opening PX_OP.

The color filters CF may be disposed on the insulating layer TINS and the black matrix BM. The color filters CF may be disposed in the openings B_OP, respectively. A planarization insulating layer PINS may be disposed on the color filters CF. The planarization insulating layer PINS may provide a flat upper surface.

When external light travelling toward the display panel DP is reflected from the display panel DP and provided back to the user, the user may visually recognize the external light as in a mirror. To prevent such a phenomenon, the anti-reflective layer RPL may include the plurality of color filters CF that display the same colors as those of the pixels PX of the display panel DP, for example. The color filters CF may filter the external light with the same colors as the pixels PX. In this case, the external light may not be visible to the user.

However, the disclosure is not limited thereto, and the anti-reflective layer RPL may include a polarizer film to decrease the reflectance of external light. The polarizer film may be separately manufactured and may be attached to the input sensing unit ISP by an adhesive layer. The polarizer film may include a phase retarder and/or a polarizer.

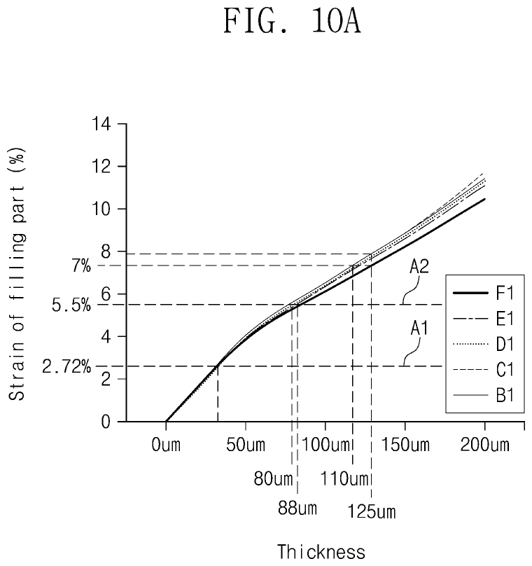

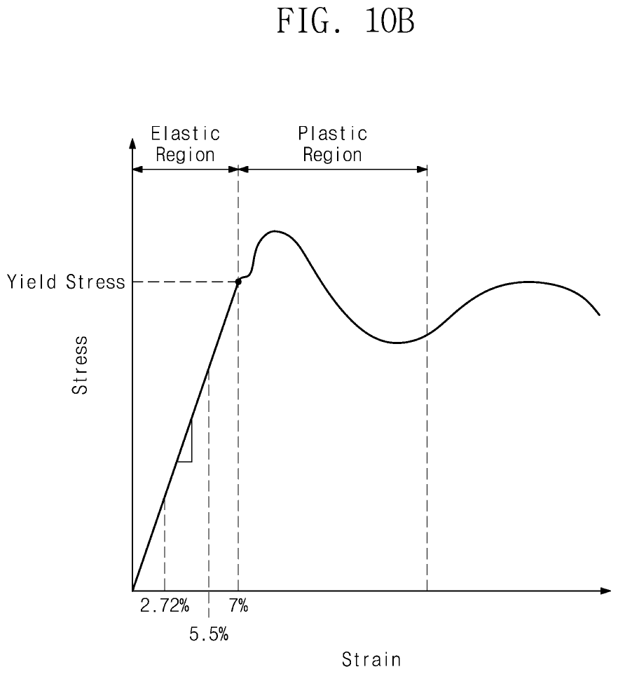

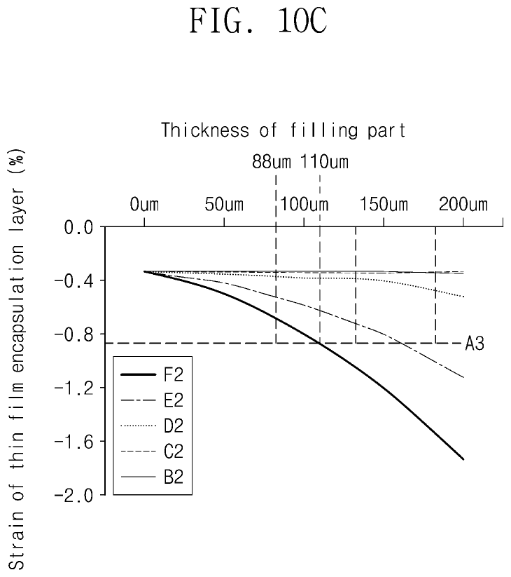

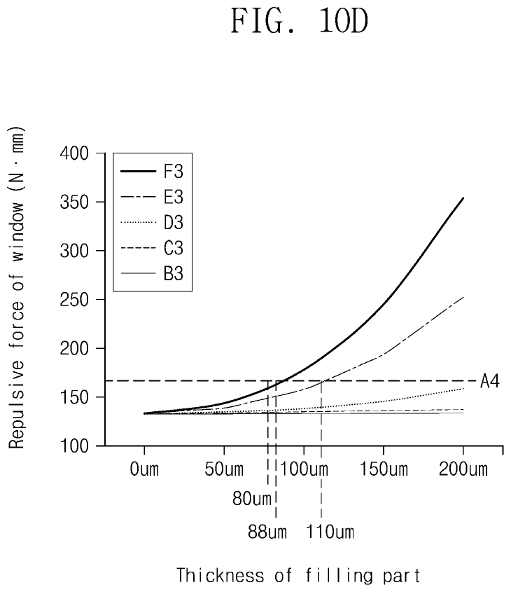

FIG. 9A is a cross-sectional view taken along line I-I′ illustrated in FIG. 7. FIG. 9B is a view illustrating a state in which the bending region illustrated in FIG. 9A is bent. FIG. 10A is a view for explaining yield strain of a filling part illustrated in FIG. 9A. FIG. 10B is a view for explaining yield strain. FIG. 10C is a view for explaining strain of the thin film encapsulation layer illustrated in FIG. 5. FIG. 10D is a view for explaining a repulsive force of a window illustrated in FIG. 9A.

In an embodiment, FIG. 9A is a view illustrating a portion of a display part DSP, a portion of a support plate PLT, and a portion of the window module WM, for example.

Referring to FIG. 9A, the display device DD may include the display part DSP, the window module WM disposed on the display part DSP, and the support plate PLT disposed under the display part DSP. The support plate PLT may support the display module DM. The window module WM may include the window WIN, a window protection layer WP, a hard coating layer HC, and first and second adhesive layers AL1 and AL2.

The display part DSP may include the electronic panel EP, an impact absorbing layer ISL, the panel protection layer PPL, the filling part FCHa, a barrier layer BRL, and third to sixth adhesive layers AL3 to AL6. The impact absorbing layer ISL, the electronic panel EP, the third adhesive layer AL3 may be defined as the display module DM. In another embodiment, the fourth adhesive layer AL4a may be also defined as the display module DM. The configuration of the electronic panel EP has been described above in detail with reference to FIG. 5, and therefore description thereabout will be omitted.

The impact absorbing layer ISL may be disposed on the electronic panel EP. The impact absorbing layer ISL may protect the electronic panel EP by absorbing an external impact applied from above the display device DD toward the electronic panel EP. The impact absorbing layer ISL may be manufactured in the form of a stretchable film.

The impact absorbing layer ISL may include a flexible plastic material. The flexible plastic material may be defined as a synthetic resin film. In an embodiment, the impact absorbing layer ISL may include a flexible plastic material such as PI or PET, for example.

The window WIN may be disposed on the impact absorbing layer ISL. The window WIN may protect the electronic panel EP from external scratches. The window WIN may have a property of being optically clear. The window WIN may include glass. However, without being limited thereto, the window WIN may include a synthetic resin film.

The window WIN may have a multi-layer structure or a single-layer structure. In an embodiment, the window WIN may include a plurality of synthetic resin films coupled by an adhesive, or may include a glass substrate and a synthetic resin film coupled by an adhesive, for example.

The window protection layer WP may be disposed on the window WIN. The window protection layer WP may include a flexible plastic material such as PI or PET. The hard coating layer HC may be disposed on an upper surface of the window protection layer WP.

A printed layer PIT may be disposed on a lower surface of the window protection layer WP. The printed layer PIT may be black in color. However, the color of the printed layer PIT is not limited thereto. The printed layer PIT may be adjacent to the periphery of the window protection layer WP.

The panel protection layer PPL may be disposed under the electronic panel EP. The panel protection layer PPL may protect a lower portion of the electronic panel EP.

In an embodiment, the panel protection layer PPL may have a thickness of about 75 micrometers (μm), for example. However, without being limited thereto, the panel protection layer PPL may have a thickness of about 55 μm to about 95 μm.

The panel protection layer PPL may include a flexible plastic material. In an embodiment, the panel protection layer PPL may include PET, for example.

The panel protection layer PPL may include a first panel protection layer PPL1 and a second panel protection layer PPL2. The first panel protection layer PPL1 may overlap the first non-folding region NFA1. The second panel protection layer PPL2 may overlap the second non-folding region NFA2.

The first panel protection layer PPL1 and the second panel protection layer PPL2 may be spaced apart from each other in the first direction DR1. The first panel protection layer PPL1 and the second panel protection layer PPL2 may be spaced apart from each other by the length of the folding region FA in the first direction DR1. The first panel protection layer PPL1 and the second panel protection layer PPL2 may not overlap the folding region FA.

The fourth adhesive layer AL4a that will be described below may be disposed between the panel protection layer PPL and the electronic panel EP. In an embodiment, the fourth adhesive layer AL4a may have a thickness of about 13 μm, for example. In an embodiment, the fourth adhesive layer AL4a may have an elastic modulus of about 105 kilopascals (kPa). Detailed description of the fourth adhesive layer AL4a will be given below, for example.

The filling part FCHa may be disposed under the electronic panel EP. The filling part FCHa may be disposed between the first panel protection layer PPL1 and the second panel protection layer PPL2. The filling part FCHa may overlap the folding region FA.

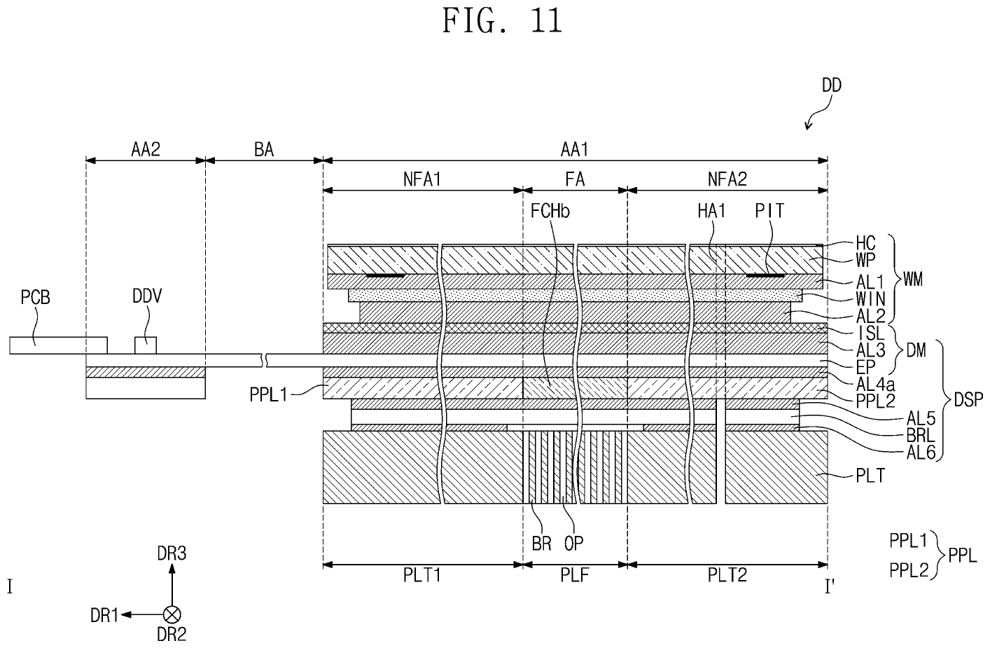

In an embodiment, the thickness of the filling part FCHa in the third direction DR3 may be less than the thickness of the first and second panel protection layers PPL1 and PPL2 in the third direction DR3, for example. A lower surface of the filling part FCHa may have a height greater than the heights of lower surfaces of the first and second panel protection layers PPL1 and PPL2. However, this is illustrative, and the height of the lower surface of the filling part FCHa may be equal to the heights of the lower surfaces of the first and second panel protection layers PPL1 and PPL2. Detailed description thereabout will be given below with reference to FIG. 11.

Referring to FIGS. 9A, 10A, and 10B, a 1-1 graph A1 and a 1-2 graph A2 are graphs depicting strains when the panel protection layer PPL overlapping the folding region FA is folded in a case in which the panel protection layer PPL extends from the first non-folding region NFA1 to the second non-folding region NFA2 via the folding region FA. An embodiment representing the results of the 1-1 and 1-2 graphs and may be an embodiment in the prior art.

A 2-1 graph B1 is a graph depicting strain when a filling part FCHa having an elastic modulus of about 1 megapascal (Mpa) is folded. A 3-1 graph C1 is a graph depicting strain when a filling part FCHa having an elastic modulus of about 10 Mpa is folded. A 4-1 graph D1 is a graph depicting strain when a filling part FCHa having an elastic modulus of about 100 Mpa is folded. A 5-1 graph E1 is a graph depicting strain when a filling part FCHa having an elastic modulus of about 500 Mpa is folded. A 6-1 graph F1 is a graph depicting strain when a filling part FCHa having an elastic modulus of about 1 gigapascal (Gpa) is folded.

An elastic region in FIG. 10B may be defined as a section in which an object returns to its original state when a force applied to the object is removed. A plastic region in FIG. 10B may be defined as a section in which the object is permanently deformed. In the elastic region, stress may be proportional to strain. In the elastic region, an elastic modulus may be the slope of the graph illustrated in FIG. 10B.

Strain may be defined as the ratio of the amount of change in the length of the filling part FCHa to the initial length of the filling part FCHa. The magnitude of applied stress when the filling part FCHa starts to permanently deform without maintaining elasticity may be defined as yield stress. That is, the yield stress may be defined as stress at the boundary between the elastic region and the plastic region.

Yield strain may be defined as strain of the object when the yield stress is applied to the object. For convenience of description, the yield strain is indicated as about 7% in FIG. 10B, for example. In an embodiment, FIG. 10B is a strain-stress curve of the embodiment representing the results of the 1-1 and 1-2 graphs A1 and A2 illustrated in FIG. 10A, for example.

In the case of the embodiment representing the results of the 1-1 graph A1 and the 1-2 graph A2, the strain when the panel protection layer PPL overlapping the folding region FA is folded may range from about 2.72% to about 5.5%. Accordingly, when the filling part FCHa is disposed in a region overlapping a folding portion, the strain of the filling part FCHa may also be up to about 5.5%. To allow the filling part FCHa to be repeatedly folded or unfolded while maintaining elasticity, the strain of the filling part FCHa may be within the elastic region in FIG. 10B.

In an embodiment, when the filling part FCHa has the yield strain of about 7% as illustrated in FIG. 10B, the filling part FCHa may be repeatedly folded or unfolded without being permanently deformed even though stress causing a strain of up to about 5.5% is applied, for example. Although it has been described that the yield strain is about 7%, the yield strain of the filling part FCHa may range from about 5.5% to about 7%.

Referring to FIGS. 6, 9A, 10A, and 10C, a 1-3 graph A3 is a graph depicting strain when the thin film encapsulation layer TFE disposed over the panel protection layer PPL is folded in the case in which the panel protection layer PPL extends from the first non-folding region NFA1 to the second non-folding region NFA2 via the folding region FA. An embodiment representing the result of the 1-3 graph A3 may be an embodiment in the prior art. In the embodiment representing the result of the 1-3 graph A3, the thin film encapsulation layer TFE may not be permanently deformed or damaged even through repeatedly folded or unfolded.

Because the thin film encapsulation layer TFE is disposed over the panel protection layer PPL in FIG. 9A, the thin film encapsulation layer TFE may be compressed when folded. Accordingly, the length of the deformed thin film encapsulation layer TFE after the compression may be shorter than the initial length of the thin film encapsulation layer TFE. Thus, the strain of the thin film encapsulation layer TFE may have a negative value.

A 2-2 graph B2 is a graph depicting strain when the thin film encapsulation layer TFE is folded in a case in which a filling part FCHa having an elastic modulus of about 1 Mpa is disposed. A 3-2 graph C2 is a graph depicting strain when the thin film encapsulation layer TFE is folded in a case in which a filling part FCHa having an elastic modulus of about 10 Mpa is disposed. A 4-2 graph D2 is a graph depicting strain when the thin film encapsulation layer TFE is folded in a case in which a filling part FCHa having an elastic modulus of about 100 Mpa is disposed. A 5-2 graph E2 is a graph depicting strain when the thin film encapsulation layer TFE is folded in a case in which a filling part FCHa having an elastic modulus of about 500 Mpa is disposed. A 6-2 graph F2 is a graph depicting strain when the thin film encapsulation layer TFE is folded in a case in which a filling part FCHa having an elastic modulus of about 1 Gpa is disposed.

As illustrated in FIG. 10A, the thickness of the filling part FCHa may range from about 80 μm to about 125 μm when the strain of the filling part FCHa ranges from about 5.5% to about 7%. However, as illustrated in FIG. 10C, when the filling part FCHa has a thickness of more than about 110 μm, the strain of the thin film encapsulation layer TFE may be greater than that in the embodiment representing the result of the 1-3 graph A3. In this case, the thin film encapsulation layer TFE may be cracked. When the filling part FCHa has a thickness of about 80 μm to about 110 μm, the strain of the thin film encapsulation layer TFE in the embodiment representing the results of the 2-2 to 6-2 graphs B2 to F2 may be less than or equal to the strain of the thin film encapsulation layer TFE in the embodiment representing the result of the 1-3 graph A3.

Accordingly, to prevent the thin film encapsulation layer TFE from being cracked, the filling part FCHa may have a thickness of about 80 μm to about 110 μm. Even though the filling part FCHa having a thickness of about 80 μm to about 110 μm overlaps the folding region FA and is disposed in a region between the first and second panel protection layers PPL1 and PPL2, the thin film encapsulation layer TFE may not be permanently deformed or damaged by a folding or unfolding operation.

Referring to FIGS. 9A, 10A, and 10D, when viewed in the second direction DR2, the window WIN may also be folded when the display device DD is folded. Specifically, a portion of the window WIN that overlaps the first non-folding region NFA1 may be rotated in the clockwise direction on the plane defined by the first direction DR1 and the third direction DR3. A portion of the window WIN that overlaps the second non-folding region NFA2 may be rotated in the counterclockwise direction on the plane defined by the first direction DR1 and the third direction DR3. In this case, the window WIN may have a repulsive force against the rotation.

A 1-4 graph A4 is a graph depicting a repulsive force of the window WIN when the window WIN is folded in the case in which the panel protection layer PPL extends from the first non-folding region NFA1 to the second non-folding region NFA2 via the folding region FA. An embodiment representing the result of the 1-4 graph may be an embodiment in the prior art. In the embodiment representing the result of the 1-4 graph, the window WIN may not be damaged even though repeatedly folded or unfolded.

A 2-3 graph B3 is a graph depicting a repulsive force of the window WIN when a filling part FCHa having an elastic modulus of about 1 Mpa is disposed. A 3-3 graph C3 is a graph depicting a repulsive force of the window WIN when a filling part FCHa having an elastic modulus of about 10 Mpa is disposed. A 4-3 graph D3 is a graph depicting a repulsive force of the window WIN when a filling part FCHa having an elastic modulus of about 100 Mpa is disposed. A 5-3 graph E3 is a graph depicting a repulsive force of the window WIN when a filling part FCHa having an elastic modulus of about 500 Mpa is disposed. A 6-3 graph F3 is a graph depicting a repulsive force of the window WIN when a filling part FCHa having an elastic modulus of about 1 Gpa is disposed.

The thickness of the filling part FCHa may be set depending on the magnitude of an elastic modulus of the filling part FCHa. When the filling part FCHa has a thickness of about 110 μm, the repulsive force of the window WIN in the embodiment representing the result of the graph 5-3 E3 may be equal to the repulsive force of the window WIN in the embodiment representing the result of the 1-4 graph A4. However, when the filling part FCHa has a thickness of about 88 μm, the repulsive force of the window WIN in the embodiment representing the result of the graph 6-3 F3 may be equal to the repulsive force of the window WIN in the embodiment representing the result of the 1-4 graph A4.

TABLE 1

| | Panel | | | | | | | |
|---|---|---|---|---|---|---|---|---|
| | protection | | | | | | | |
| | layer | 90 | | 200 | | 300 | | 400 |
| | PPL | Mpa | | Mpa | | Mpa | | Mpa |
| Force causing | 15 kgf | 5.8 | kgf | 7.9 | kgf | 9.0 | kgf | 10.6 kgf |
| bright spot on | | | | | | | | |
| display surface | | | | | | | | |
| DS (refer | | | | | | | | |
| to FIG. 1) | | | | | | | | |
| Force causing | 15 kgf | 12.2 | kgf | 14.3 | kgf | 15.4 | kgf | 16.3 kgf |

crack in
window

Table 1 relates to experimental examples for identifying the impact resistance of the folding region FA (refer to FIG. 9A). An impact resistance test may be performed through a nail press test. The nail press test may be a test in which an object having a relatively small contact area, such as a fingernail or a nail, is pressed against the display surface DS (refer to FIG. 1) of the display device DD.

Referring to Table 1, in an embodiment in which the panel protection layer PPL extends from the first non-folding region NFA1 to the second non-folding region NFA2 via the folding region FA and is not divided in the folding region FA, a bright spot may occur on the display surface DS (refer to FIG. 1) when a force of about kilograms-force (kgf) is applied to the display surface DS (refer to FIG. 1). The window WIN may be cracked when the force of about 15 kgf is applied to the window WIN.

In an embodiment in which the filling part FCHa is disposed to overlap the folding region FA, the magnitude of a force by which a bright spot on the display surface DS and a crack in the window WIN start to occur may vary depending on the elastic modulus of the filling part FCHa. As the elastic modulus of the filling part FCHa is increased, the magnitude of the force that causes the bright spot on the display surface DS and the crack in the window WIN may be increased.

As seen from Table 1, a bright spot may occur when the filling part FCHa has an elastic modulus of about 400 Mpa or more and a force of about 10.6 kgf is applied. The window WIN may be cracked when the filling part FCHa has an elastic modulus of about 400 Mpa or more and a force of about 16.3 kgf is applied. When the filling part FCHa has an elastic modulus of about 400 Mpa, the result may be similar to the experimental result value in the embodiment in which the panel protection layer PPL overlaps the folding region FA. Accordingly, the elastic modulus of the filling part FCHa may range from about 400 Mpa to about 1 Gpa.

As described with reference to FIGS. 10A to 10D and Table 1, the yield strain of the filling part FHCa may range from about 5.5% to about 7%. The thickness of the filling part FCHa may range from about 80 μm to about 110 μm. The elastic modulus of the filling part FCHa may range from about 400 Mpa to about 1 Gpa.

In an embodiment in which the panel protection layer PPL overlaps the first non-folding region NFA1, the folding region FA, and the second non-folding region NFA2, the panel protection layer PPL disposed in the first and second non-folding regions NFA1 and NFA2 and the folding region FA may include the same material as each other. The panel protection layer PPL disposed in the first and second non-folding regions NFA1 and NFA2 and the folding region FA may be unitary.

To improve the impact resistance of the first and second non-folding regions NFA1 and NFA2, the thickness of the panel protection layer PPL may be increased from about 50 μm to about 75 μm. The thickness of the panel protection layer PPL overlapping the folding region FA may also be increased. In this case, when the electronic device ED (refer to FIG. 1) is folded, the electronic device ED may not be easily folded due to the increase in the thickness of the panel protection layer PPL overlapping the folding region FA.

However, according to the disclosure, the panel protection layer PPL overlapping the first and second non-folding region NFA1 and NFA2 and the filling part FCHa overlapping the folding region FA may include different materials from each other. The panel protection layer PPL overlapping the first and second non-folding region NFA1 and NFA2 and the filling part FCHa overlapping the folding region FA may not be unitary.

Accordingly, the filling part FCHa may have an elastic modulus and a yield strain different from those of the panel protection layer PPL. In addition, the thickness of the filling part FCHa may be adjusted to be different from the thickness of the panel protection layer PPL. Accordingly, the filling part FCHa and the electronic device ED (refer to FIG. 1) may be easily folded while the improved impact resistance of the first and second non-folding regions NFA1 and NFA2 is maintained.

The barrier layer BRL may be disposed under the panel protection layer PPL. The barrier layer BRL may increase resistance to a compressive force caused by external pressing. Accordingly, the barrier layer BRL may serve to prevent deformation of the electronic panel EP. The barrier layer BRL may include a flexible plastic material such as PI or PET.

The barrier layer BRL may have a color that absorbs light. In an embodiment, the barrier layer BRL may be black in color, for example. In this case, components disposed under the barrier layer BRL may not be visible when the display module DM is viewed from above the display module DM.

The first adhesive layer AL1 may be disposed between the window protection layer WP and the window WIN. The window protection layer WP and the window WIN may be bonded to each other by the first adhesive layer AL1. The first adhesive layer AL1 may cover the printed layer PIT.

The second adhesive layer AL2 may be disposed between the window WIN and the impact absorbing layer ISL. The window WIN and the impact absorbing layer ISL may be bonded to each other by the second adhesive layer AL2.

The third adhesive layer AL3 may be disposed between the impact absorbing layer ISL and the electronic panel EP. The impact absorbing layer ISL and the electronic panel EP may be bonded to each other by the third adhesive layer AL3.

The fourth adhesive layer AL4a may be disposed between the electronic panel EP and the panel protection layer PPL. The fourth adhesive layer AL4a may be disposed between the electronic panel EP and the filling part FCHa. The electronic panel EP and the panel protection layer PPL may be bonded to each other by the fourth adhesive layer AL4a. The electronic panel EP and the filling part FCHa may be bonded to each other by the fourth adhesive layer AL4a.

The fifth adhesive layer AL5 may be disposed between the panel protection layer PPL and the barrier layer BRL. The fifth adhesive layer AL5 may be disposed between the filling part FCHa and the barrier layer BRL. The panel protection layer PPL and the barrier layer BRL may be bonded to each other by the fifth adhesive layer AL5. In an embodiment, the filling part FCHa may be spaced apart from the fifth adhesive layer AL5 in the third direction DR3, for example. However, without being limited thereto, the filling part FHCa may be brought into contact with an upper surface of the fifth adhesive layer AL5. Detailed description thereabout will be given below with reference to FIG. 11.

The sixth adhesive layer AL6 may be disposed between the barrier layer BRL and the support plate PLT. Specifically, the support plate PLT may be disposed under the barrier layer BRL, and the sixth adhesive layer AL6 may be disposed between the barrier layer BRL and the support plate PLT. The barrier layer BRL and the support plate PLT may be bonded to each other by the sixth adhesive layer AL6.

The sixth adhesive layer AL6 may overlap the first and second non-folding regions NFA1 and NFA2 and may not overlap the folding region FA. That is, the sixth adhesive layer AL6 may not be disposed in the folding region FA.

The first to sixth adhesive layers AL1 to AL6 may include a transparent adhesive such as a pressure sensitive adhesive (“PSA”) or an optically clear adhesive (“OCA”), but are not limited thereto.

The thickness of the panel protection layer PPL may be less than the thickness of the window protection layer WP, and the thickness of the barrier layer BRL may be less than the thickness of the panel protection layer PPL. The thickness of the electronic panel EP may be less than the thickness of the barrier layer BRL and may be equal to the thickness of the window WIN. The thickness of the impact absorbing layer ISL may be less than the thickness of the electronic panel EP.

The thickness of the first adhesive layer AL1 may be equal to the thickness of the barrier layer BRL, and the thicknesses of the second adhesive layer AL2 and the third adhesive layer AL3 may be equal to the thickness of the panel protection layer PPL. The thickness of the fourth adhesive layer AL4 may be equal to the thickness of the fifth adhesive layer AL5.

The thicknesses of the fourth adhesive layer AL4a and the fifth adhesive layer AL5 may be less than the thickness of the electronic panel EP and may be greater than the thickness of the impact absorbing layer ISL. The thickness of the sixth adhesive layer AL6 may be less than the thickness of the impact absorbing layer ISL. The thickness of the hard coating layer HC may be less than the thickness of the sixth adhesive layer AL6.

The electronic panel EP, the impact absorbing layer ISL, the panel protection layer PPL, and the third and fourth adhesive layers AL3 and AL4 may have the same width. The window protection layer WP and the first adhesive layer AL1 may have the same width. The barrier layer BRL and the fifth and sixth adhesive layers AL5 and AL6 may have the same width.

The widths of the electronic panel EP, the impact absorbing layer ISL, the panel protection layer PPL, and the third and fourth adhesive layers AL3 and AL4 may be greater than the widths of the window protection layer WP and the first adhesive layer AL1. The peripheries of the electronic panel EP, the impact absorbing layer ISL, the panel protection layer PPL, and the third and fourth adhesive layers AL3 and AL4 may be disposed outward of the peripheries of the window protection layer WP and the first adhesive layer AL1.

The widths of the window WIN and the second adhesive layer AL2 may be less than the widths of the window protection layer WP and the first adhesive layer AL1. The width of the second adhesive layer AL2 may be less than the width of the window WIN. The periphery of the window WIN may be disposed inward of the peripheries of the window protection layer WP and the first adhesive layer AL1. The periphery of the second adhesive layer AL2 may be disposed inward of the periphery of the window WIN.

The widths of the barrier layer BRL and the fifth and sixth adhesive layers AL5 and AL6 may be less than the widths of the window protection layer WP and the first adhesive layer AL1. The peripheries of the barrier layer BRL and the fifth and sixth adhesive layers AL5 and AL6 may be disposed inward of the peripheries of the window protection layer WP and the first adhesive layer AL1.

The support plate PLT may be disposed under the display part DSP and may support the display part DSP. The support plate PLT may be disposed under the electronic panel EP and may support the electronic panel EP. The width of the support plate PLT may be substantially the same as the width of the electronic panel EP. The support plate PLT may have a higher rigidity than that of the display part DSP.

The support plate PLT may include a non-metallic material. In an embodiment, the support plate PLT may include a fiber reinforced composite, for example. The fiber reinforced composite may be carbon fiber reinforced plastic (“CFRP”) or glass fiber reinforced plastic (“GFRP”).

The support plate PLT including the fiber reinforced composite may be lightened. The support plate PLT including the fiber reinforced composite may be lighter than a metal support plate including or consisting of a metallic material and may have a modulus and rigidity similar to those of the metal support plate.

In addition, the support plate PLT including the fiber reinforced composite may be more easily shaped than the metal support plate. In an embodiment, the support plate PLT including the fiber reinforced composite may be more easily shaped through a laser process or a micro-blast process, for example.

The support plate PLT may include a first non-folding portion PLT1, a folding portion PLF, and a second non-folding portion PLT2. The first non-folding portion PLT1 may overlap the first non-folding region NFA1. The folding portion PLF may overlap the folding region FA. The second non-folding portion PLT2 may overlap the second non-folding region NFA2. In an embodiment, a hole area HA1 corresponding to a hole in the second non-folding portion PLT2 may be defined in the second non-folding region NFA2.

A plurality of openings OP may be defined in the folding portion PLF. The openings OP may be defined through portions of the support plate PLT in the third direction DR3. The openings OP, when viewed in the second direction DR2, may be defined in the first direction DR1 so as to be spaced apart from each other. The openings OP may be defined through the laser process or the micro-blast process described above. The width of the portion in which the openings OP are defined may be less than the width of the opening of the sixth adhesive layer AL6.

Because the openings OP are defined in the portion of the support plate PLT that overlaps the folding region FA, the flexibility of the portion of the support plate PLT that overlaps the folding region FA may be increased. Thus, the support plate PLT may be folded about the folding region FA.

The folding portion PLF may include branch portions BR. Each of the branch portions BR may be disposed between the openings OP adjacent to each other in the first direction DR1. More detailed shapes of the openings OP and the branch portions BR will be described below in detail with reference to FIGS. 10A to 10C.

Although not illustrated, the display device DD may further include a digitizer, a shielding layer, and a heat radiating layer that are disposed under the support plate PLT.

Referring to FIG. 9B, the panel protection layer PPL and the fourth adhesive layer AL4a may not be disposed under the bending region BA. The panel protection layer PPL and the fourth adhesive layer AL4a may be disposed under the second region AA2 of the electronic panel EP. The data driver DDV may be disposed under the second region AA2 of the electronic panel EP.

A printed circuit board PCB may be connected to the second region AA2 of the electronic panel EP. The printed circuit board PCB may be connected to one side of the second region AA2. As the bending region BA is bent, the second region AA2 may be disposed under the first region AA1. Accordingly, the data driver DDV and the printed circuit board PCB may be disposed under the first region AA1.

FIG. 11 is a view illustrating an embodiment of a display device.

In an embodiment, FIG. 11 is a cross-sectional view of the display device DD viewed in the second direction DR2, for example.

A window module WM, a display module DM, fourth to sixth adhesive layers AL4a, AL5, and AL6, a barrier layer BRL, and a support plate PLT of FIG. 11 are the same as the window module WM, the display module DM, the fourth to sixth adhesive layers AL4a, AL5, and AL6, the barrier layer BRL, and the support plate PLT of FIG. 9A and therefore will be omitted from the description or will be briefly described.

Referring to FIG. 11, a filling part FCHb may be disposed between first and second panel protection layers PPL1 and PPL2 spaced apart from each other in the first direction DR1. The filling part FCHb may overlap a folding region FA.

The thickness of the filling part FCHb in the third direction DR3 may be equal to the thickness of the first and second panel protection layers PPL1 and PPL2 in the third direction DR3. The height of a lower surface of the filling part FCHb may be equal to the heights of lower surfaces of the first and second panel protection layers PPL1 and PPL2.

The lower surface of the filling part FCHb may be brought into contact with an upper surface of the fifth adhesive layer AL5. The filling part FCHb and the barrier layer BRL may be bonded to each other by the fifth adhesive layer AL5.

Because the filling part FCHb having an elastic modulus and a yield strain different from those of the first and second panel protection layers PPL1 and PPL2 is disposed to overlap the folding region FA, the impact resistance of first and second non-folding regions NFA1 and NFA2 may be improved, and the display device DD may be easily folded.

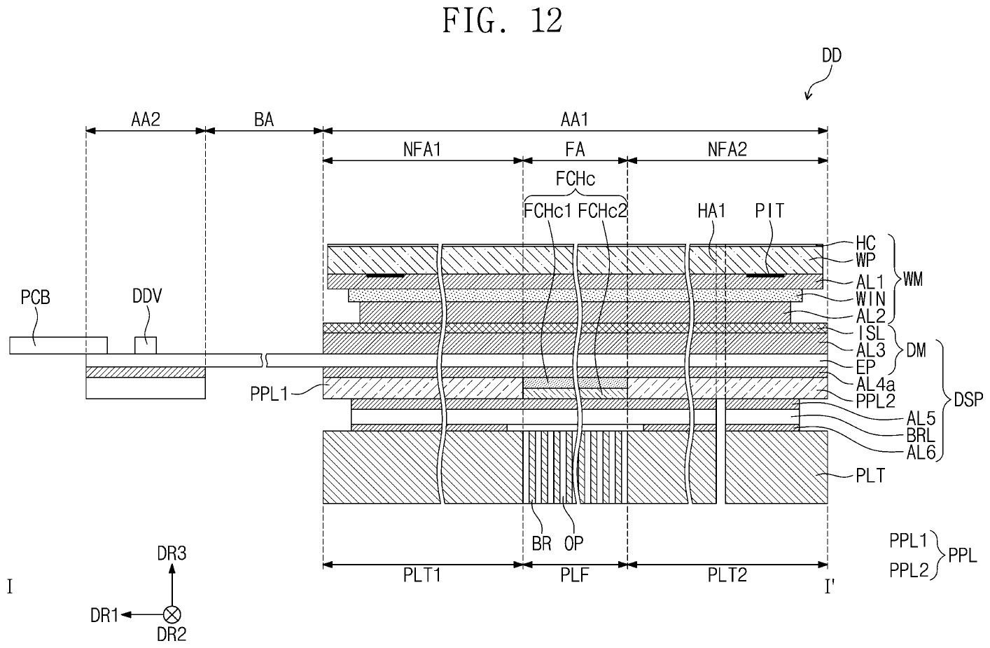

FIG. 12 is a view illustrating an embodiment of a display device according to the disclosure.

In an embodiment, FIG. 12 is a cross-sectional view of the display device DD viewed in the second direction DR2, for example.

A window module WM, a display module DM, fourth to sixth adhesive layers AL4a, AL5, and AL6, a barrier layer BRL, and a support plate PLT of FIG. 12 are the same as the window module WM, the display module DM, the fourth to sixth adhesive layers AL4a, AL5, and AL6, the barrier layer BRL, and the support plate PLT of FIG. 9A and therefore will be omitted from the description or will be briefly described.

Referring to FIG. 12, a filling part FCHc may be disposed between first and second panel protection layers PPL1 and PPL2 spaced apart from each other in the first direction DR1. The filling part FCHc may overlap a folding region FA.

In an embodiment, the thickness of the filling part FCHc in the third direction DR3 may be equal to the thickness of the first and second panel protection layers PPL1 and PPL2 in the third direction DR3, for example. The height of a lower surface of the filling part FCHc may be equal to the heights of lower surfaces of the first and second panel protection layers PPL1 and PPL2. However, without being limited thereto, the thickness of the filling part FCHc may be less than the thickness of the panel protection layer PPL. In this case, the lower surface of the filling part FCHc may have a height greater than the height of the lower surface of the panel protection layer PPL.

The filling part FCHc may include a first filling part FCHc1 and a second filling part FCHc2. The first filling part FCHc1 may be disposed under an electronic panel EP. The first filling part FCHc1 may be disposed on a lower surface of the fourth adhesive layer AL4a. The first filling part FCHc1 and the electronic panel EP may be bonded to each other by the fourth adhesive layer AL4a.

The second filling part FCHc2 may be disposed under the first filling part FCHc1. The second filling part FCHc2 may be disposed between the first filling part FCHc1 and the fifth adhesive layer AL5. The second filling part FCHc2 may be disposed on a lower surface of the first filling part FCHc1.

In an embodiment, the thickness of the second filling part FCHc2 may be equal to the thickness of the first filling part FCHc1, for example. However, without being limited thereto, the thickness of the second filling part FCHc2 may be different from the thickness of the first filling part FCHc1.

In an embodiment, the sum of the thickness of the first filling part FCHc1 and the thickness of the second filling part FCHc2 may be equal to the thickness of the panel protection layer PPL, for example. The height of a lower surface of the second filling part FCHc2 may be equal to the height of the lower surface of the panel protection layer PPL.

However, without being limited thereto, the sum of the thickness of the first filling part FCHc1 and the thickness of the second filling part FCHc2 may be less than the thickness of the panel protection layer PPL. In this case, the lower surface of the second filling part FCHc2 may have a height greater than the height of the lower surface of the panel protection layer PPL.

Because the filling part FCHc having an elastic modulus, a yield strain, and a thickness different from those of the panel protection layer PPL is disposed to overlap the folding region FA, the impact resistance of first and second non-folding regions NFA1 and NFA2 may be improved, and the display device DD may be easily folded.

Although the filling part FCHc including the two layers is illustrated in an embodiment, the filling part FCHc is not limited thereto and may include three or more layers.

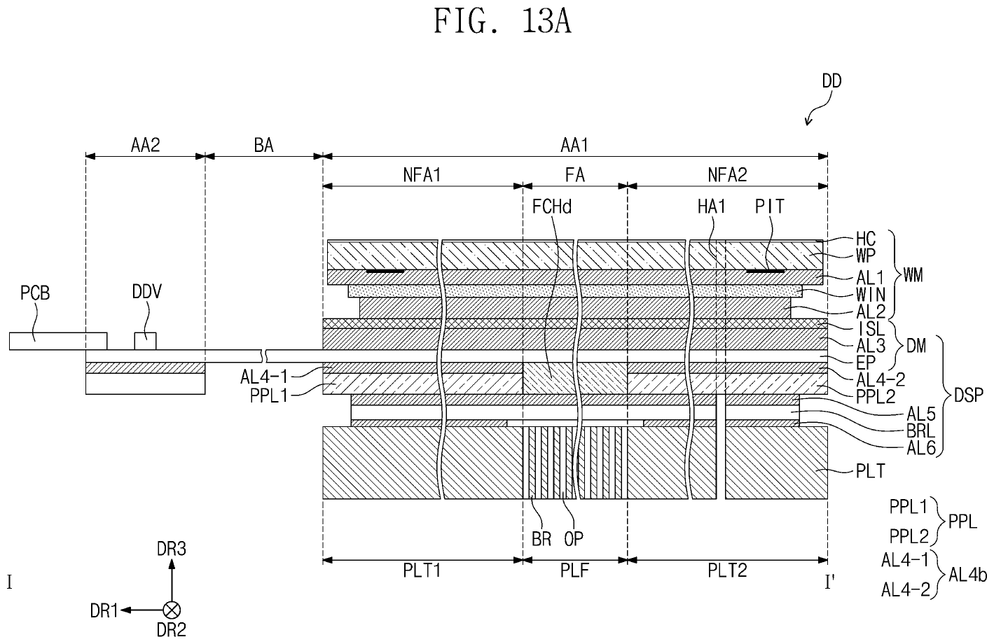

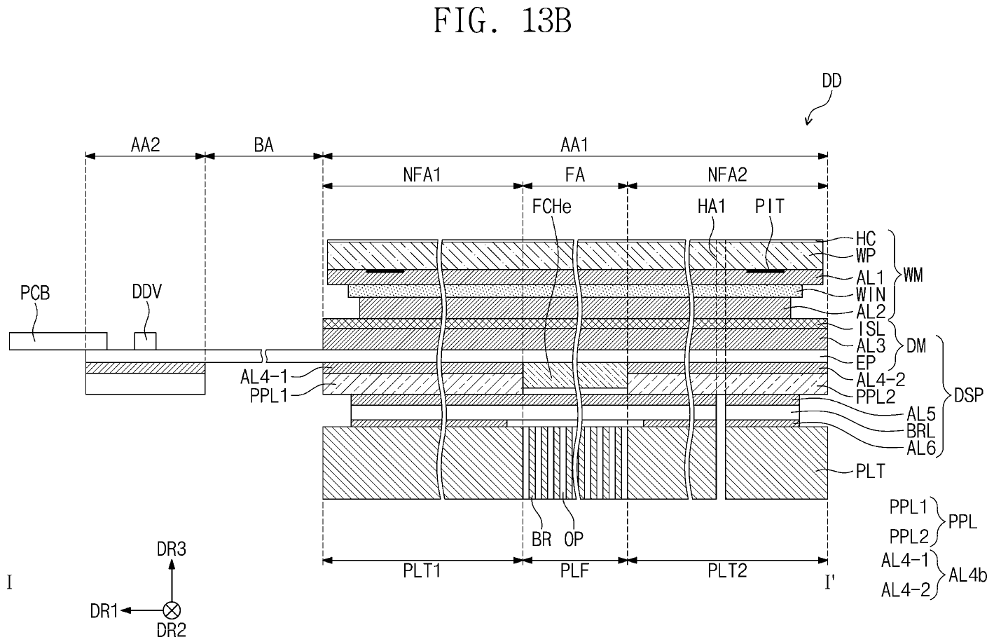

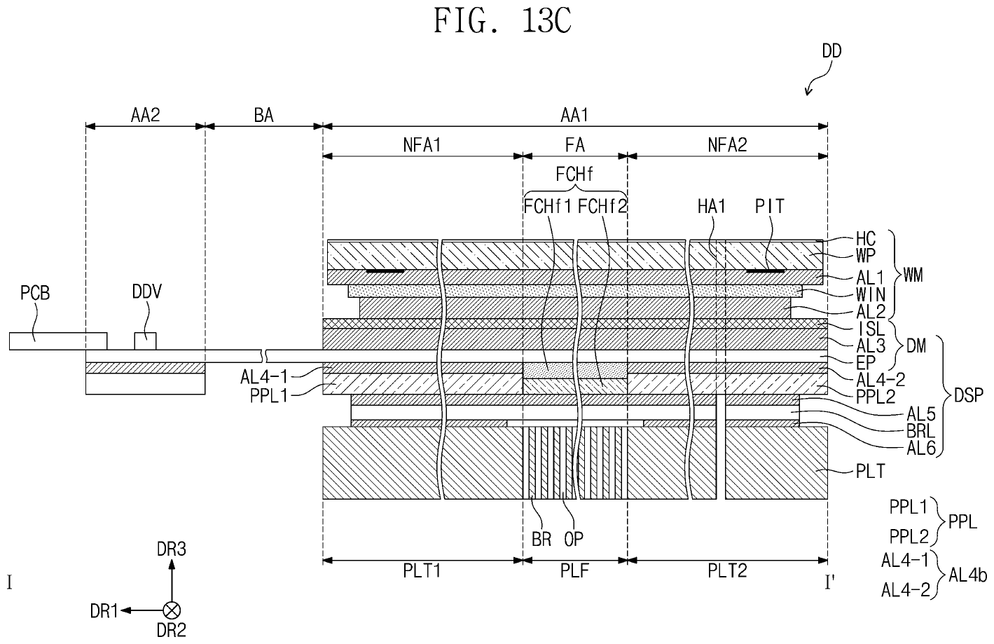

FIGS. 13A to 13C are views for explaining an embodiment of a display device.

In an embodiment, FIGS. 13A to 13C are cross-sectional views of the display device DD viewed in the second direction DR2, for example.

A window module WM, a display module DM, fifth and sixth adhesive layers AL5 and AL6, and a support plate PLT of FIGS. 13A to 13C are the same as the window module WM, the display module DM, the fifth and sixth adhesive layers AL5 and AL6, and the support plate PLT of FIG. 9A and therefore will be omitted from the description or will be briefly described.

Referring to FIGS. 13A to 13C, a fourth adhesive layer AL4b may include a first portion AL4-1 and a second portion AL4-2. The first portion AL4-1 and the second portion AL4-2 may be spaced apart from each other in the first direction DR1 and may be disposed on a lower surface of an electronic panel EP.

The first portion AL4-1 may overlap a first non-folding region NFA1. The first portion AL4-1 may overlap a first panel protection layer PPL1. The first panel protection layer PPL1 and the electronic panel EP may be bonded to each other by the first portion AL4-1.

The second portion AL4-2 may overlap a second non-folding region NFA2. The second portion AL4-2 may overlap a second panel protection layer PPL2. The second panel protection layer PPL2 and the electronic panel EP may be bonded to each other by the second portion AL4-2. The first portion AL4-1 and the second portion AL4-2 may not overlap a folding region FA.

In an embodiment, the first portion AL4-1 and the second portion AL4-2 may have an elastic modulus of about 105 kPa, for example. In an embodiment, the first portion AL4-1 and the second portion AL4-2 may have a thickness of about 13 μm, for example.

Referring to FIG. 13A, a filling part FCHd may be disposed between the first portion AL4-1 and the second portion AL4-2 spaced apart from each other in the first direction DR1. The filling part FCHd may be disposed between the first panel protection layer PPL1 and the second panel protection layer PPL2 spaced apart from each other in the first direction DR1.

The filling part FCHd may be disposed on the lower surface of the electronic panel EP. The filling part FCHd may include an adhesive material. Accordingly, the filling part FCHd may be directly disposed on the lower surface of the electronic panel EP and may be bonded to the lower surface of the electronic panel EP.

The thickness of the filling part FCHd may be equal to the sum of the thickness of the fourth adhesive layer AL4b and the thickness of the panel protection layer PPL. In this case, the height of a lower surface of the filling part FCHd may be equal to the height of a lower surface of the panel protection layer PPL.

Referring to FIG. 13B, a filling part FCHe may be disposed between the first portion AL4-1 and the second portion AL4-2 spaced apart from each other in the first direction DR1. The filling part FCHe may be disposed between the first panel protection layer PPL1 and the second panel protection layer PPL2 spaced apart from each other in the first direction DR1.

The filling part FCHe may be disposed on the lower surface of the electronic panel EP. The filling part FCHe may include an adhesive material. Accordingly, the filling part FCHe may be directly disposed on the lower surface of the electronic panel EP.

The thickness of the filling part FCHe may be less than the sum of the thickness of the fourth adhesive layer AL4b and the thickness of the panel protection layer PPL. In this case, a lower surface of the filling part FCHe may have a height greater than the height of the lower surface of the panel protection layer PPL.

Referring to FIG. 13C, a filling part FCHf may be disposed between the first portion AL4-1 and the second portion AL4-2 spaced apart from each other in the first direction DR1. The filling part FCHf may be disposed between the first panel protection layer PPL1 and the second panel protection layer PPL2 spaced apart from each other in the first direction DR1.

The filling part FCHf may include a third filling part FCHf1 and a fourth filling part FCHf2. The third filling part FCHf1 and the fourth filling part FCHf2 may include an adhesive material. The third filling part FCHf1 may be disposed under the electronic panel EP. The third filling part FCHf1 may be directly disposed on the lower surface of the electronic panel EP.

The fourth filling part FCHf2 may be disposed under the third filling part FCHf1. The fourth filling part FCHf2 may be directly disposed on a lower surface of the third filling part FCHf1.

The third filling part FCHf1 and the fourth filling part FCHf2 are illustrated as having the same thickness. However, without being limited thereto, the third filling part FCHf1 and the fourth filling part FCHf2 may have different thicknesses.

In an embodiment, the sum of the thickness of the third filling part FCHf1 and the thickness of the fourth filling part FCHf2 may be equal to the sum of the thickness of the fourth adhesive layer AL4b and the thickness of the panel protection layer PPL, for example. In this case, the height of a lower surface of the fourth filling part FCHf2 may be equal to the height of the lower surface of the panel protection layer PPL.

This is illustrative, and although not illustrated, the sum of the thickness of the third filling part FCHf1 and the thickness of the fourth filling part FCHf2 may be less than the sum of the thickness of the fourth adhesive layer AL4b and the thickness of the panel protection layer PPL. In this case, the lower surface of the fourth adhesive layer AL4b may have a height greater than the height of the lower surface of the panel protection layer PPL.

Although the filling part FCHf including the two layers is illustrated in an embodiment, the filling part FCHf is not limited thereto and may include three or more layers.

Referring to FIGS. 13A to 13C, each of the fourth adhesive layer AL4b and the panel protection layer PPL may not be divided in the region overlapping the folding region FA. The fourth adhesive layer AL4b may extend from the first non-folding region NFA1 to the second non-folding region NFA2 via the folding region FA. The panel protection layer may extend from the first non-folding region NFA1 to the second non-folding region NFA2 via the folding region FA. That is, the fourth adhesive layer AL4b disposed in the first non-folding region NFA1, the folding region FA, and the second non-folding region NFA2 may be unitary. The panel protection layer PPL disposed in the first non-folding region NFA1, the folding region FA, and the second non-folding region NFA2 may be unitary.

When the thicknesses and elastic moduli of the fourth adhesive layer AL4b and the panel protection layer PPL are increased to improve the impact resistance of the first non-folding region NFA1 and the second non-folding region NFA2, the thicknesses and elastic moduli of the fourth adhesive layer AL4b and the panel protection layer PPL that overlap the folding region FA may also be increased. Accordingly, when the electronic device ED (refer to FIG. 1) is folded, the electronic device ED may not be easily folded.

However, in the embodiments of the disclosure, the filling part FCHd, FCHe, or FCHf may be disposed between the first portion AL4-1 and the second portion AL4-2 separated from each other and between the first panel protection layer PPL1 and the second panel protection layer PPL2 separated from each other and may overlap the folding region FA. That is, the filling part FCHd, FCHe, or FCHf may be separated from the fourth adhesive layer AL4b and the panel protection layer PPL. Accordingly, the filling part FCHd, FCHe, or FCHf having a thickness, an elastic modulus, and a yield strain different from those of the fourth adhesive layer AL4b and the panel protection layer PPL may be disposed in the folding region FA. Thus, the impact resistance of the first and second non-folding regions NFA1 and NFA2 may be improved, and the electronic device ED (refer to FIG. 1) may be easily folded.

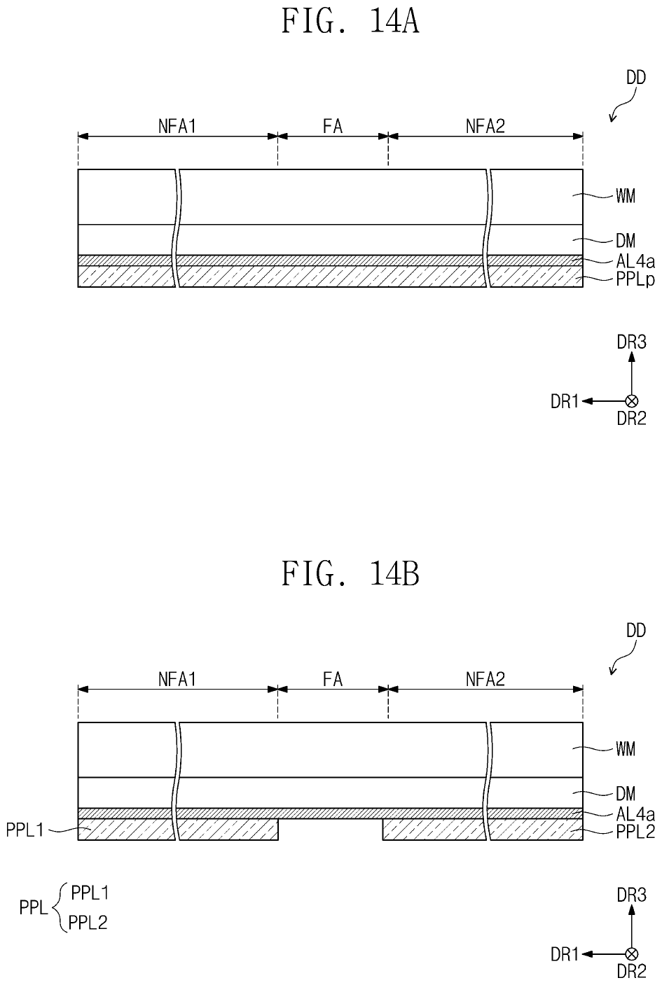

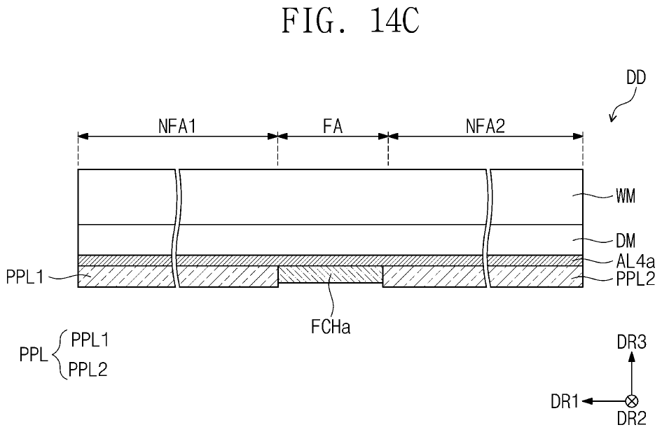

FIGS. 14A to 14C are views for explaining a method of manufacturing the display device illustrated in FIG. 9A.

In an embodiment, FIGS. 14A to 14C are cross-sectional views of the display device DD viewed in the second direction DR2, for example.

Among the components illustrated in FIG. 9A, the remaining components other than the window module WM, the display module DM, the fourth adhesive layer AL4a, and the panel protection layer PPL are omitted in FIGS. 14A to 14C.

For convenience of description, the window module WM and the display module DM are briefly illustrated as one layer in FIGS. 14A to 14C.

The window module WM, the display module DM, and the fourth adhesive layer AL4a of FIGS. 14A to 14C are the same as the window module WM, the display module DM, and the fourth adhesive layer AL4a of FIG. 9A and therefore will be omitted from the description or will be briefly described.

Referring to FIG. 14A, the window module WM may be provided on the display module DM. A step of providing the fourth adhesive layer AL4a on the lower surface of the display module DM may be performed. The fourth adhesive layer AL4a may contact the first non-folding region NFA1, the folding region FA, and the second non-folding region NFA2.

After the fourth adhesive layer AL4a is disposed on the lower surface of the display module DM, a preliminary panel protection layer PPLP may be disposed under the fourth adhesive layer AL4a. The preliminary panel protection layer PPLP may overlap the first non-folding region NFA1, the folding region FA, and the second non-folding region NFA2. The preliminary panel protection layer PPLP and the display module DM may be bonded to each other by the fourth adhesive layer AL4a.

After the preliminary panel protection layer PPLP is disposed, a process of etching the preliminary panel protection layer PPLP overlapping the folding region FA may be performed. In an embodiment, a portion of the preliminary panel protection layer PPLP that overlaps the folding region FA may be removed by ultraviolet light, for example. However, without being limited thereto, a portion of the preliminary panel protection layer PPLP may be removed through another process.

In an embodiment, in FIG. 14B, it has been described that a portion of the preliminary panel protection layer PPLP is removed, for example. However, without being limited thereto, a portion of the fourth adhesive layer AL4a that overlaps the folding region FA may be removed.

When a portion of the preliminary panel protection layer PPLP is removed, the panel protection layer PPL may be divided in the first direction DR1. The first panel protection layer PPL1 and the second panel protection layer PPL2 may be formed in the first direction DR1.

Referring to FIG. 14C, the filling part FCHa may be disposed between the first panel protection layer PPL1 and the second panel protection layer PPL2. The filling part FCHa may be disposed on the lower surface of the fourth adhesive layer AL4a. In an embodiment, the filling part FCHa may be filled by an ink-jet method, for example. However, without being limited thereto, the filling part FCHa may be filled by another method.

Although not illustrated, the filling part FCHa may be directly disposed on the lower surface of the display module DM as illustrated in FIG. 13A when the fourth adhesive layer AL4a overlapping the folding region FA is removed.

In an embodiment, the thickness of the filling part FCHa disposed between the first panel protection layer PPL1 and the second panel protection layer PPL2 may be less than the thickness of the panel protection layer PPL, for example. The height of the lower surface of the filling part FCHa may be greater than the height of the lower surface of the panel protection layer PPL.

However, without being limited thereto, the height of the lower surface of the filling part FCHa may be equal to the height of the lower surface of the panel protection layer PPL. This has been described with reference to FIG. 11, and therefore the description will be omitted.

Because the first panel protection layer PPL1 and the second panel protection layer PPL2 are separated from the filling part FCHa, the filling part FCHa having a thickness, an elastic modulus, and a yield strain different from those of the fourth adhesive layer AL4a and the panel protection layer PPL may be disposed in the folding region FA. Thus, the impact resistance of the first and second non-folding regions NFA1 and NFA2 may be improved, and the electronic device ED (refer to FIG. 1) may be easily folded.

By the embodiments of the disclosure, the filling part disposed in the region overlapping the folding region may be disposed between the panel protection layers overlapping the non-folding regions. The filling part and the panel protection layers may include different materials and may have different elastic moduli. Accordingly, the impact resistance of the non-folding regions may be improved, and the folding region may be easily folded.

While the disclosure has been described with reference to embodiments thereof, it will be apparent to those of ordinary skill in the art that various changes and modifications may be made thereto without departing from the spirit and scope of the disclosure as set forth in the following claims.

What is claimed is:

1. A display device comprising:
a display panel including a first non-folding region, a folding region, and a second non-folding region arranged in a first direction;
a plurality of panel protection layers disposed under the first non-folding region and the second non-folding region; and
a filling part which is disposed between the plurality of panel protection layers and overlaps the folding region,
wherein a lower surface of the filling part has a height greater than or equal to each of heights of lower surfaces of the plurality of panel protection layers.

2. The display device of claim 1, further comprising:
an adhesive layer disposed between the plurality of panel protection layers and the display panel and between the filling part and the display panel.

3. The display device of claim 2, wherein the filling part has a higher elastic modulus than a modulus of the adhesive layer.

4. The display device of claim 2, wherein the filling part includes:
a first filling part disposed on a lower surface of the adhesive layer; and
a second filling part disposed on a lower surface of the first filling part.

5. The display device of claim 4, wherein a lower surface of the second filling part has a height greater than or equal to each of the heights of the lower surfaces of the plurality of panel protection layers.

6. The display device of claim 1, further comprising:
an adhesive layer disposed between the plurality of panel protection layers and the display panel,
wherein the adhesive layer does not overlap the folding region, and the filling part is directly disposed on a lower surface of the display panel.

7. The display device of claim 6, wherein the filling part includes:
a third filling part directly disposed on the lower surface of the display panel; and
a fourth filling part directly disposed on a lower surface of the third filling part.

8. The display device of claim 7, wherein a lower surface of the fourth filling part has a height greater than or equal to each of the heights of the lower surfaces of the plurality of panel protection layers.

9. The display device of claim 1, wherein the filling part has an elastic modulus of about 400 megapascals to about 1 gigapascal.

10. The display device of claim 9, wherein the filling part has a thickness of about 80 micrometers to about 110 micrometers.

11. The display device of claim 10, wherein the filling part has a yield strain of about 5.5 percent to about 7 percent.

12. A display device comprising:
a display panel including a first non-folding region, a folding region, and a second non-folding region arranged in a first direction;
an adhesive layer disposed under the display panel;
a plurality of panel protection layers disposed under the adhesive layer and spaced apart from each other in the folding region; and
a filling part which is disposed between the plurality of panel protection layers and overlaps the folding region,
wherein the filling part has a thickness less than or equal to a sum of a thickness of the plurality of panel protection layers and a thickness of the adhesive layer.

13. The display device of claim 12, wherein a lower surface of the filling part has a height greater than or equal to each of heights of lower surfaces of the plurality of panel protection layers.

14. The display device of claim 13, wherein the adhesive layer extends from the first non-folding region to the second non-folding region via the folding region, and
wherein the filling part is disposed on a lower surface of the adhesive layer.

15. The display device of claim 14, wherein the filling part includes:
a first filling part disposed on the lower surface of the adhesive layer; and
a second filling part disposed on a lower surface of the first filling part, and
wherein a lower surface of the second filling part has a height greater than or equal to each of the heights of the lower surfaces of the plurality of panel protection layers.

16. The display device of claim 13, wherein the adhesive layer includes:
a first portion overlaps the first non-folding region; and
a second portion overlaps the second non-folding region, and
wherein the adhesive layer does not overlap the folding region, and the filling part is directly disposed on a lower surface of the display panel.

17. The display device of claim 16, wherein the filling part includes:
a third filling part directly disposed on the lower surface of the display panel; and
a fourth filling part disposed on a lower surface of the third filling part, and
wherein a lower surface of the fourth filling part has a height greater than or equal to each of the heights of the lower surfaces of the plurality of panel protection layers.

18. The display device of claim 12, wherein the filling part has an elastic modulus of about 400 megapascals to about 1 gigapascal, a thickness of about 80 micrometers to about 110 micrometers, and a yield strain of about 5.5 percent to about 7 percent.

19. A method for manufacturing a display device, the method comprising:
providing an adhesive layer under a display panel including a first non-folding region, a folding region, and a second non-folding region arranged in a first direction;
providing a preliminary panel protection layer under the adhesive layer;
forming panel protection layers by removing a portion of the preliminary panel protection layer which overlaps the folding region; and
filling a filling part in a space which overlaps the folding region and is defined between the panel protection layers,
wherein a lower surface of the filling part has a height greater than or equal to each of heights of lower surfaces of the panel protection layers.

20. The method of claim 19, wherein the removing the portion of the preliminary panel protection layer includes removing a portion of the adhesive layer which is disposed between the preliminary panel protection layer and the display panel and overlaps the folding region, and
wherein the filling part is directly disposed on a lower surface of the display panel.
